(19) United States
(12) Patent Application Publication
(10) Pub. No.: US 2024/0124665 A1
(43) Pub. Date: Apr. 18, 2024

(54) POLYETHYLENE COPOLYMERS AND TERPOLYMERS FOR SOLAR CELL ENCAPSULATION AND METHODS THEREOF

(71) Applicant: Braskem S.A., Camaçari (BR)

(72) Inventors: Murilo Lauer Sanson, São Paulo City (BR); Hadi Mohammadi, Philadelphia, PA (US); Nei Sebastião Domingues Junior, São Paulo City (BR)

(73) Assignee: Braskem S.A., Camaçari (BR)

(21) Appl. No.: 18/374,910

(22) Filed: Sep. 29, 2023

Related U.S. Application Data
(60) Provisional application No. 63/412,199, filed on Sep. 30, 2022.
(60) Provisional application No. 63/412,127, filed on Sep. 30, 2022.

(51) Int. Cl. C08J 5/18; B29C 48/00; B29C 48/08; B32B 17/10; B32B 27/06; B32B 27/16; B32B 27/26; B32B 27/30; B32B 37/10; C08L 23/08

(52) U.S. Cl. CPC C08J 5/18; B29C 48/022; B29C 48/08; B32B 17/10678; B32B 17/10697; B32B 17/10788; B32B 27/06; B32B 27/16; B32B 27/26; B32B 27/30; B32B 37/1018; C08L 23/0853; B29C 2948/92152; B32B 2250/03; B32B 2305/72; B32B 2307/7376; C08J 2323/08; C08L 2203/204

(57) ABSTRACT

Provided is a film comprising a polymer composition comprising a polymer produced from ethylene, one or more branched vinyl ester monomers, and optionally, vinyl acetate, with an ethylene content in an amount ranging from 40 to 99.9 wt %, and having a melt index (I₂) from 0.1 to 100 g/10 min ASTM D1238 (190° C. and load of 2.16 kg). Also provided are a method of producing a film, an article comprising a film, a solar cell encapsulant comprising a film, a laminate comprising a film and a method of manufacturing an article.

### BACKGROUND

Solar cell encapsulants made of ethylene vinyl acetate (EVA) copolymers have issues with degradation, especially in environments of high humidity, temperature and solar incidence. This can result in acetic acid generation (causing corrosion in metallic parts of the module), browning discoloration (which can lead to decreased light transmittance and absorption due to chromophore groups formation), as well as losing adhesion and flexibility, all of which are detrimental to the performance of a solar cell and present challenges to the goal of a 30 year life-time.

Current alternatives to EVA are materials such as ionomers, polyolefin elastomers (POEs), thermoplastic olefins (TPOs), and poly(siloxanes) (silicones). Although ionomers have superior performance (especially with higher electrical resistivity and transmittance, and lower moisture vapor transmission rate), they are usually more expensive than EVA, and therefore do not have such a large market acceptance. Poly dimethyl siloxane (PDMS), the first material used as encapsulant for photovoltaic (PV) modules, runs into similar problems. Despite superior performance (especially in terms of light transmittance), the high cost makes it attractive only for niche, very specific and demanding applications.

POEs on the other hand, which are newer materials in the market, are used in two approaches: crosslinked or as a thermoplastic. The crosslinked version of these films is manufactured into film using a similar process to current EVA films. Peroxide, silane, and additives are blended with POE polymers and the mixture is fabricated into a film with either extrusion or calendaring processes, often designed to be used in the same solar module manufacturing equipment with similar production cycle times as EVA. On the other hand, for the thermoplastic version, silane additives used to ensure adhesion must be grafted prior to production of the film, and also, it must ensure mechanical stability for temperatures up to 105° C. Longer use lifetimes can be achieved through elimination of degradation mechanisms associated with acetic acid from the EVA. However, POEs usually present lower adhesion capabilities, and run into issues like high cost and availability in the solar energy market.

For EVA, the aforementioned degradation phenomena are triggered/accelerated by exposure to UV radiation, heat, moisture, oxygen, and the catalytic activity of acetic acid. Therefore, there exists a continuing need for cost-effective materials that have reduced issues with hydrolysis and UV degradation.

### BRIEF DESCRIPTION OF DRAWINGS

FIG. 1 shows a lamination cycle.

FIG. 2 shows schematics of the lamination process.

FIG. 3 shows laminated samples.

FIG. 4 shows initial UV-VIS spectroscopy of the laminated samples.

FIG. 5 shows spectra of the lamps used in the UV degradation tests and damp heat tests.

FIG. 6 shows UV degradation testing results.

FIG. 7 shows a comparison in transmittance of DV001A vs EVATANE.

FIG. 8 shows a comparison in transmittance of DV001B vs EVATANE.

FIG. 9 shows a comparison in transmittance of HM728 vs EVATANE.

FIG. 10 shows calculated indexes from numerical integration data—angular coefficient (m).

FIG. 11 shows calculated indexes from numerical integration data—linear coefficient (b).

FIG. 12 shows the linear coefficient from measured values (initial transmittance—b0).

FIG. 13 shows transmittance of samples during the Damp Heat Test—65° C., 85% relative humidity, UV lamp.

FIG. 14 shows transmittance of EVATANE and DV001A during the damp heat test.

FIG. 15 shows transmittance of EVATANE and DV001B during the damp heat test.

FIG. 16 shows transmittance of EVATANE and HM728 during the damp heat test.

FIG. 17 shows initial transmittance of DV001A, DV001B, HM728 and Evatane during damp heat test.

FIG. 18 shows plateau transmittance (linear fit) during damp heat test.

FIG. 19a shows the difference between initial and plateau transmittances (linear fit) during damp heat test—absolute value.

FIG. 19b shows the difference between initial and plateau transmittances (linear fit) during damp heat test—normalized value w/initial transmittance.

FIG. 20 shows schematics of the adhesion test sample laminated.

FIG. 21 shows plots of force vs displacement, highlighting the region used for work and energy calculation, with highlight of region not considered for HM728.

FIG. 22 shows plots of force vs displacement, highlighting the region used for average force.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a film comprising a polymer composition comprising a polymer produced from ethylene, one or more branched vinyl ester monomers, and optionally, vinyl acetate, with an ethylene content in an amount ranging from 40 to 99.9 wt %, and having a melt index (I₂) from 0.1 to 100 g/10 min, measured according to ASTM D1238 (190° C. and load of 2.16 kg).

In another aspect, embodiments disclosed herein relate to method of producing the a film comprising a polymer composition comprising a polymer produced from ethylene, one or more branched vinyl ester monomers, and optionally, vinyl acetate, with an ethylene content in an amount ranging from 40 to 99.9 wt %, and having a melt index (I₂) from 0.1 to 100 g/10 min, measured according to ASTM D1238 (190° C. and load of 2.16 kg), the method comprising blending the polymer composition, comprising a polymer produced from ethylene, one or more branched vinyl ester monomers, and optionally, vinyl acetate; and optionally: a peroxide; a crosslinking coagent; a primary antioxidant; a secondary antioxidant; a light stabilizer; an UV absorber; an adhesion promoter, and thermal stabilizers, plasticizers, rubbers/elastomers, fillers, and combinations thereof; where the blending method comprises using a twin screw extruder, single screw extruder, kneader, banbury mixer, mixing roller, or a cast film extruder; and producing a film having a thickness in the range of 5 to 800 μm, via cast film extrusion, blown film extrusion, or calendaring.

In another aspect, embodiments disclosed herein relate to an article comprising a substrate and a film comprising a polymer composition comprising a polymer produced from ethylene, one or more branched vinyl ester monomers, and optionally, vinyl acetate, with an ethylene content in an amount ranging from 40 to 99.9 wt %, and having a melt index (I₂) from 0.1 to 100 g/10 min, measured according to ASTM D1238 (190° C. and load of 2.16 kg).

In another aspect, embodiments disclosed herein relate to a solar cell encapsulant comprising a film comprising a polymer composition comprising a polymer produced from ethylene, one or more branched vinyl ester monomers, and optionally, vinyl acetate, with an ethylene content in an amount ranging from 40 to 99.9 wt %, and having a melt index (I₂) from 0.1 to 100 g/10 min, measured according to ASTM D1238 (190° C. and load of 2.16 kg), wherein the film is crosslinked.

In another aspect, embodiments disclosed herein relate to a laminate comprising a glass substrate and a film comprising a polymer composition comprising a polymer produced from ethylene, one or more branched vinyl ester monomers, and optionally, vinyl acetate, with an ethylene content in an amount ranging from 40 to 99.9 wt %, and having a melt index (I₂) from 0.1 to 100 g/10 min, measured according to ASTM D1238 (190° C. and load of 2.16 kg), wherein the film is on the glass substrate.

In another aspect, embodiments disclosed herein relate to method of manufacturing an article, comprising applying a film comprising a polymer composition comprising a polymer produced from ethylene, one or more branched vinyl ester monomers, and optionally, vinyl acetate, with an ethylene content in an amount ranging from 40 to 99.9 wt %, and having a melt index (I₂) from 0.1 to 100 g/10 min, measured according to ASTM D1238 (190° C. and load of 2.16 kg) to a substrate.

Other aspects and advantages of the claimed subject matter will be apparent from the following description and the appended claims.

### DETAILED DESCRIPTION

Embodiments disclosed herein relate to films comprising a polymer composition comprising a polymer produced from ethylene, one or more branched vinyl ester monomers, and optionally, vinyl acetate, with an ethylene content in an amount ranging from 40 to 99.9 wt %. In one or more embodiments, polymer compositions may be prepared from a reaction of ethylene and one or more branched vinyl esters and/or vinyl acetate monomers that modify various properties of the formed copolymer, and films formed therefrom, including density; melt index (I₂); melting temperature; electrical resistivity; hardness; softening point; optical transmittance; haze; water vapor transmission; mechanical strength; UV cut-off wavelength; gloss; crystallinity; and glass transition temperature, among others.

Advantageously, the present disclosure aims to reduce issues associated with hydrolysis and degradation described above for EVA through the use of co- and ter-polymers of ethylene and a branched vinyl ester, and optionally vinyl acetate. The inclusion of branched vinyl ester instead of or in conjunction with vinyl acetate may decrease water vapor transmission rate (WVTR) and acetic acid generation, while enhancing low temperature flexibility.

### Polymer Compositions

### Co- and Ter-Polymers

Co- and ter-polymers of the present disclosure may be produced from ethylene, one or more branched vinyl ester monomers, and optionally, vinyl acetate, with an ethylene content in an amount ranging from 40 to 99.9 wt %.

### Branched Vinyl Ester Monomers

In one or more embodiments, branched vinyl esters may include branched vinyl esters generated from isomeric mixtures of branched alkyl acids. Branched vinyl esters in accordance with the present disclosure may have the general chemical formula (I):

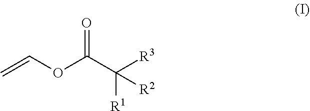

where R¹, R², and R³ have a combined carbon number in the range of C3 to C20. In some embodiments, R¹, R², and R³ may all be alkyl chains having varying degrees of branching in some embodiments, or a subset of R¹, R², and R³ may be independently selected from a group consisting of hydrogen, alkyl, or aryl in some embodiments.

In one or more embodiments, the vinyl carbonyl monomers may include branched vinyl esters having the general chemical formula (II):

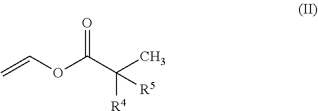

wherein R⁴ and R⁵ have a combined carbon number of 6 or 7 and the polymer composition has a number average molecular weight (Mₙ) ranging from 5 kDa to 10000 kDa obtained by GPC. In one or more embodiments, R⁴ and R⁵ may have a combined carbon number of less than 6 or greater than 7, and the polymer composition may have an Mₙ up to 10000 kDa. That is, when the Mₙ is less than 5 kDa, R⁴ and R⁵ may have a combined carbon number of less than 6 or greater than 7, but if the Mₙ is greater than 5 kDa, such as in a range from 5 to 10000 kDa, R⁴ and R⁵ may include a combined carbon number of 6 or 7. In particular embodiments, R⁴ and R⁵ have a combined carbon number of 7, and the Mₙ may range from 5 to 10000 kDa. Further in one or more particular embodiments, a vinyl carbonyl according to Formula (II) may be used in combination with vinyl acetate.

Examples of branched vinyl esters may include monomers having the chemical structures, including derivatives thereof:

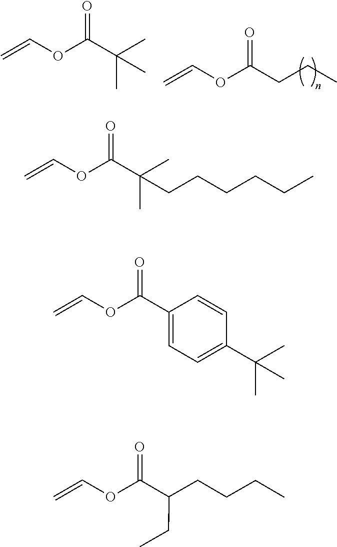

In one or more embodiments, the polymer compositions may include polymers generated from monomers derived from petroleum and/or renewable sources.

In one or more embodiments, branched vinyl esters may include monomers and comonomer mixtures containing vinyl esters of neononanoic acid, neodecanoic acid, and the like. In some embodiments, branched vinyl esters may include Versatic™ acid series tertiary carboxylic acids, including Versatic™ acid EH, Versatic™ acid 9 and Versatic™ acid 10 prepared by Koch synthesis, commercially available from Hexion™ chemicals. In one or more embodiments, the polymer compositions may include polymers generated from monomers derived from petroleum and/or renewable sources.

Co- or ter-polymers that include a branched vinyl ester monomer in accordance with the present disclosure may include a percent by weight of ethylene measured by proton nuclear magnetic resonance (¹H NMR) and Carbon 13 nuclear magnetic resonance (¹³C NMR) that ranges from a lower limit selected from one of 40 wt %, 45 wt %, 50 wt %, 55 wt %, 60 wt %, 65 wt % 70 wt %, and 75 wt %, to an upper limit selected from one of 75 wt % 80 wt %, 85 wt %, 90 wt %, 95 wt %, 99 wt %, or 99.9 wt % where any lower limit may be paired with any upper limit.

Co- or ter-polymers that include a branched vinyl ester monomer in accordance with the present disclosure may include a percent by weight of vinyl ester monomer, such as that of Formula (I) and (II) above, measured by ¹H NMR and ¹³C NMR that ranges from a lower limit selected from one of 0.01 wt %, 0.1 wt %, 1 wt %, 5 wt %, 10 wt %, 20 wt %, or 30 wt % to an upper limit selected from 30 wt %, 35 wt %, 40 wt %, 45 wt %, 50 wt %, 55 wt %, or 60 wt % where any lower limit may be paired with any upper limit.

In some embodiments, co- or ter-polymers that include a branched vinyl ester monomer in accordance with the present disclosure may optionally include a percent by weight of vinyl acetate measured by ¹H NMR and ¹³C NMR that ranges from a lower limit selected from one of 0 wt %, 0.01 wt %, 0.1 wt %, 1 wt %, 5 wt %, 10 wt %, 20 wt %, 25 wt % or 30 wt % to an upper limit selected from 30 wt %, 35 wt %, 40 wt %, 45 wt %, 50 wt %, 55 wt %, or 59.99 wt % where any lower limit may be paired with any upper limit. For the polymer samples containing the vinyl acetate and vinyl ester monomers, incorporation may be determined using quantitative ¹³C NMR, since the ¹H NMR contains significant overlap in both the carbonyl and alkyl regions for accurate integration. Evidence of incorporation of the branched vinyl ester and vinyl acetate is seen in both the carbonyl (170-180 ppm) and alkyl regions (0-50 ppm) of the ¹³C NMR spectra (TCE-D₂, 393.1 K, 125 MHz). ¹H NMR spectra (TCE-D₂, 393.2 K, 500 MHz) exhibit peaks for vinyl acetate and branched vinyl ester (4.7-5.2 ppm) and ethylene (1.2-1.5 ppm) as well as additional peaks in the alkyl region (0.5-1.5 ppm) indicative of the long alkyl chains on the branched vinyl ester monomers. Relative intensity of the peaks found in ¹H NMR and ¹³C NMR spectra are used to calculate monomer incorporation of branched vinyl ester and vinyl acetate in the co-/terpolymers.

Co- or ter-polymers that include a branched vinyl ester monomer in accordance with the present disclosure may have a number average molecular weight (Mₙ) in kilodaltons (kDa) measured by gel permeation chromatography (GPC) that ranges from a lower limit selected from one of 1 kDa, 5 kDa, 10 kDa, 15 kDa, and 20 kDa to an upper limit selected from one of 40 kDa, 50 kDa, 100 kDa, 300 kDa, 500 kDa, 1000 kDa, 5000 kDa, and 10000 kDa, where any lower limit may be paired with any upper limit.

Co- or ter-polymers that include a branched vinyl ester monomer in accordance with the present disclosure may have a weight average molecular weight (M_{w}) in kilodaltons (kDa) measured by GPC that ranges from a lower limit selected from one of 1 kDa, 5 kDa, 10 kDa, 15 kDa and 20 kDa to an upper limit selected from one of 40 kDa, 50 kDa, 100 kDa, 200 kDa, 300 kDa, 500 kDa, 1000 kDa, 2000 kDa, 5000 kDa, 10000 kDa, and 20000 kDa, where any lower limit may be paired with any upper limit.

Co- or ter-polymers that include a branched vinyl ester monomer in accordance with the present disclosure may have a molecular weight distribution (MWD, defined as the ratio of M_{w} over Mₙ) measured by GPC that has a lower limit of any of 1, 1.5, 2, 5, or 10, and an upper limit of any of 20, 30, 40, 50, or 60, where any lower limit may be paired with any upper limit.

GPC analysis may be carried out in a gel permeation chromatography coupled with triple detection, with an infrared detector IR5 and a four bridge capillary viscometer, both from PolymerChar and an eight angle light scattering detector from Wyatt. A set of 4 column, mixed bed, 13 μm from Tosoh in a temperature of 140° C. may be used. The experiments may be carried out in the following conditions: concentration of 1 mg/mL, flow rate of 1 mL/min, dissolution temperature and time of 160° C. and 90 minutes, respectively and an injection volume of 200 μL. The solvent used was TCB (Trichloro benzene) stabilized with 100 ppm of BHT.

In one or more embodiments, co- or ter-polymers that includes a branched vinyl ester monomer in accordance with the present disclosure may be prepared in reactor by polymerizing ethylene and one or more branched vinyl ester monomers, and optionally a vinyl acetate comonomer, as described for example in U.S. Patent Publication No. 2021/0102014, which is herein incorporated by reference in its entirety. Methods of reacting the comonomers in the presence of a radical initiator may include any suitable method in the art including solution phase polymerization, pressurized radical polymerization, bulk polymerization, emulsion polymerization, and suspension polymerization. In some embodiments, the reactor may be a batch autoclave reactor at temperatures below 150° C. and pressures below 500 bar, known as low pressure polymerization system. In some embodiments, the comonomers and one or more free-radical polymerization initiators are polymerized in a continuous or batch process at temperatures above 150° C. and at pressures above 1000 bar, known as high pressure polymerization systems. Copolymers and terpolymers produced under high pressure conditions may have number average molecular weights of 5 to 40 kDa, weight average molecular weights of 5 to 400 kDa and MWDs of 2 to 10.

In one or more embodiments, the reaction is carried out in a low pressure polymerization process wherein the ethylene and one or more branched vinyl ester monomers, and optionally a vinyl acetate comonomer are polymerized in a liquid phase of an inert solvent and/or one or more liquid monomer(s). In one embodiment, polymerization comprises initiators for free-radical polymerization in an amount from about 0.001 to about 0.01 millimoles calculated as the total amount of one or more initiator for free-radical polymerization per liter of the volume of the polymerization zone. The amount of ethylene in the polymerization zone will depend mainly on the total pressure of the reactor in a range from about 20 bar to about 100 bar and temperature in a range from about 20° C. to about 125° C. The liquid phase of the polymerization process in accordance with the present disclosure may include ethylene, one or more branched vinyl ester monomers, and optionally a vinyl acetate comonomer, initiator for free-radical polymerization, and optionally one or more inert solvent such as tetrahydrofuran (THF), chloroform, dichloromethane (DCM), dimethyl sulfoxide (DMSO), dimethyl carbonate (DMC), hexane, cyclohexane, ethyl acetate (EtOAc) acetonitrile, toluene, xylene, ether, dioxane, dimethyl-formamide (DMF), benzene or acetone. Copolymers and terpolymers produced under low-pressure conditions may exhibit number average molecular weights of 2 to 20 kDa, weight average molecular weights of 4 to 100 kDa and MWDs of 2 to 5.

### Additives

In one or more embodiments, polymer compositions according to the present disclosure may include one or more additives including, but not limited to crosslinking agents, crosslinking coagents, primary antioxidants, secondary antioxidants, light stabilizers, UV absorbers, adhesion promoters, thermal stabilizers, plasticizers, rubbers, elastomers, fillers, and combinations thereof.

### Crosslinking Agent

Polymer compositions in accordance with the present disclosure may include at least one crosslinking agent which may comprise one or more peroxides capable of generating free radicals during polymer processing. In one or more embodiments, peroxides may include bifunctional peroxides such as benzoyl peroxide; dicumyl peroxide; di-tert-butyl peroxide; OO-Tert-amyl-O-2-ethylhexyl monoperoxycarbonate; tert-butyl cumyl peroxide; tert-butyl 3,5,5-trimethylhexanoate peroxide; tert-butyl peroxybenzoate; 2-ethylhexyl carbonate tert-butyl peroxide; 2,5-dimethyl-2,5-di (tert-butylperoxide) hexane; 1,1-di (tert-butylperoxide)-3,3,5-trimethylcyclohexane; 2,5-dimethyl-2,5-di(tert-butylperoxide) hexyne-3; 3,3,5,7,7-pentamethyl-1,2,4-trioxepane; butyl 4,4-di (tert-butylperoxide) valerate; di (2,4-dichlorobenzoyl) peroxide; di(4-methylbenzoyl) peroxide; peroxide di(tert-butylperoxyisopropyl) benzene; and the like.

Peroxides may also include benzoyl peroxide, 2,5-di(cumylperoxy)-2,5-dimethyl hexane, 2,5-di(cumylperoxy)-2,5-dimethyl hexyne-3,4-methyl-4-(t-butylperoxy)-2-pentanol, butyl-peroxy-2-ethyl-hexanoate, tert-butyl peroxypivalate, tertiary butyl peroxyneodecanoate, t-butyl-peroxy-benzoate, t-butyl-peroxy-2-ethyl-hexanoate, 4-methyl-4-(t-amylperoxy)-2-pentanol, 4-methyl-4-(cumylperoxy)-2-pentanol, 4-methyl-4-(t-butylperoxy)-2-pentanone, 4-methyl-4-(t-amylperoxy)-2-pentanone, 4-methyl-4-(cumylperoxy)-2-pentanone, 2,5-dimethyl-2,5-di(t-butylperoxy)hexane, 2,5-dimethyl-2,5-di(t-amylperoxy)hexane, 2,5-dimethyl-2,5-di(t-butylperoxy)hexyne-3,2,5-dimethyl-2,5-di(t-amylperoxy)hexyne-3,2,5-dimethyl-2-t-butylperoxy-5-hydroperoxyhexane, 2,5-dimethyl-2-cumylperoxy-5-hydroperoxy hexane, 2,5-dimethyl-2-t-amylperoxy-5-hydroperoxyhexane, m/p-alpha, alpha-di[(t-butylperoxy)isopropyl]benzene, 1,3,5-tris(t-butylperoxyisopropyl)benzene, 1,3,5-tris(t-amylperoxyisopropyl)benzene, 1,3,5-tris(cumy lperoxyisopropyl)benzene, di[1,3-dimethyl-3-(t-butylperoxy)butyl]carbonate, di[1,3-dimethyl-3-(t-amylperoxy)butyl]carbonate, di[1,3-dimethyl-3-(cumylperoxy)butyl]carbonate, di-t-amyl peroxide, t-amyl cumyl peroxide, t-butyl-isopropenylcumyl peroxide, 2,4,6-tri(butylperoxy)-s-triazine, 1,3,5-tri[1-(t-butylperoxy)-1-methylethyl]benzene, 1,3,5-tri-[(t-butylperoxy)-isopropyl]benzene, 1,3-dimethyl-3-(t-butylperoxy)butanol, 1,3-dimethyl-3-(t-amylperoxy)butanol, di(2-phenoxyethyl)peroxydicarbonate, di(4-t-butylcyclohexyl)peroxydicarbonate, dimyristyl peroxydicarbonate, dibenzyl peroxydicarbonate, di(isobomyl)peroxydicarbonate, 3-cumylperoxy-1,3-dimethylbutyl methacrylate, 3-t-butylperoxy-1,3-dimethylbutyl methacrylate, 3-t-amylperoxy-1,3-dimethylbutyl methacrylate, tri(1,3-dimethyl-3-t-butylperoxy butyloxy)vinyl silane, 1,3-dimethyl-3-(t-butylperoxy)butyl N-[1-{3-(1-methylethenyl)-phenyl) 1-methylethyl]carbamate, 1,3-dimethyl-3-(t-amylperoxy)butyl N-[1-{3(1-methylethenyl)-phenyl}-1-methylethyl]carbamate, 1,3-dimethyl-3-(cumylperoxy))butyl N-[1-{3-(1-methylethenyl)-phenyl}-1-methylethyl]carbamate, 1,1-di(t-butylperoxy)-3,3,5-trimethylcyclohexane, 1,1-di(t-butylperoxy)cyclohexane, n-butyl 4,4-di(t-amylperoxy)valerate, ethyl 3,3-di(t-butylperoxy)butyrate, 2,2-di(t-amylperoxy)propane, 3,6,6,9,9-pentamethyl-3-ethoxycabonylmethyl-1,2,4,5-tetraoxacyclononane, n-buty 1-4,4-bis(t-butylperoxy)valerate, ethyl-3,3-di(t-amylperoxy)butyrate, benzoyl peroxide, OO-t-butyl-O-hydrogen-monoperoxy-succinate, OO-t-amyl-O-hydrogen-monoperoxy-succinate, 3,6,9, triethyl-3,6,9-trimethyl-1,4,7-triperoxynonane (or methyl ethyl ketone peroxide cyclic trimer), methyl ethyl ketone peroxide cyclic dimer, 3,3,6,6,9,9-hexamethyl-1,2,4,5-tetraoxacyclononane, 2,5-dimethyl-2,5-di(benzoylperoxy)hexane, t-butyl perbenzoate, t-butylperoxy acetate, t-butylperoxy-2-ethyl hexanoate, t-amyl perbenzoate, t-amyl peroxy acetate, t-butyl peroxy isobutyrate, 3-hydroxy-1,1-dimethyl t-butyl peroxy-2-ethyl hexanoate, OO-t-amyl-O-hydrogen-monoperoxy succinate, OO-t-butyl-O-hydrogen-monoperoxy succinate, di-t-butyl diperoxyphthalate, t-butylperoxy (3,3,5-trimethylhexanoate), 1,4-bis(t-butylperoxycarbo)cyclohexane, t-butylperoxy-3,5,5-trimethylhexanoate, t-butyl-peroxy-(cis-3-carboxy)propionate, allyl 3-methyl-3-t-butylperoxy butyrate, OO-t-butyl-O-isopropylmonoperoxy carbonate, OO-t-butyl-O-(2-ethyl hexyl)monoperoxy carbonate, 1,1,1-tris[2-(t-butylperoxy-carbonyloxy)ethoxymethyl]propane, 1,1,1-tris[2-(t-amylperoxy-carbonyloxy)ethoxymethyl]propane, 1,1,1-tris[2-(cumylperoxy-cabonyloxy)ethoxymethyl]propane, OO-t-amyl-O-isopropylmonoperoxy carbonate, di(4-methylbenzoyl)peroxide, di(3-methylbenzoyl)peroxide, di(2-methylbenzoyl)peroxide, didecanoyl peroxide, dilauroyl peroxide, 2,4-dibromo-benzoyl peroxide, succinic acid peroxide, dibenzoyl peroxide, di(2,4-dichloro-benzoyl)peroxide, and combinations thereof.

The amount of the crosslinking agent may be in an amount ranging from a lower limit of 0.01, 0.1, 0.5, 1, or 2 to an upper limit of 2, 3, 4, or 5 parts per hundred rubber/resin (phr) relative to 100 phr of the polymer, where any lower limit may be used in combination with any suitable upper limit. In one or more embodiments the crosslinking agent may be in an amount ranging from 0.1 to 2.5 phr, or even in an amount from 0.5 to 2 phr.

### Crosslinking Coagent

In one or more embodiments, polymer compositions according to the present disclosure may include one or more crosslinking coagents. Crosslinking co-agents create additional reactive sites for crosslinking, allowing the degree of polymer crosslinking to be considerably increased from that normally obtained solely by the addition of peroxide. Generally, co-agents increase the rate of crosslinking. In one or more embodiments, the crosslinking co-agents may include Triallyl isocyanurate (TAIC), trimethylolpropane-tris-methacrylate (TRIM), triallyl cyanurate (TAC), trifunctional (meth)acrylate ester (TMA), N,N′-m-phenylene dimaleimide (PDM), poly(butadiene) diacrylate (PBDDA), high vinyl poly(butadiene) (HVPBD), poly-transoctenamer rubber (TOR) (Vestenamer®), and combinations thereof.

The amount of the crosslinking co-agent may be in an amount ranging from a lower limit of 0.01, 0.1, 0.5, 1, or 2 to an upper limit of 2, 2.5, 3, 3.5, 4, 4.5, or 5 parts per hundred rubber/resin (phr) relative to 100 phr of the polymer, where any lower limit may be used in combination with any suitable upper limit. In one or more embodiments the crosslinking co-agent may be in an amount ranging from 0.1 to 2.5 phr.

### Antioxidants

In one or more embodiments, polymer compositions according to the present disclosure may include one or more antioxidants. Polymer compositions according to embodiments may include at least a primary and a secondary antioxidant. Antioxidants according to the present disclosure may include monophenol-type, bisphenol-type, polymeric phenol-type, Sulfur-containing and phosphite-type antioxidants.

Monophenol-based antioxidants include, among others, 2,6-di-tert-butyl-p-cresol, butylated hydroxyanisole, 2,6-di-tert-butyl-4-ethylphenol, etc. The bisphenol type antioxidants include 2,2′-methylenebis(4-methyl-6-tert-butylphenol), 2,2′-methylenebis(4-ethyl-6-tert butylphenol), 4,4′-thiobis(3-methyl-6-tert-butylphenol), 4,4′-butylidenebis(3-methyl-6-tert-butylphenol), 3.9-bis(1,1-dimethyl-2-R-(3-tert-butyl-4-hydroxy-5-methylphenyl) propionyloxyethyl}2.4.9,10-tetroxaspiro-5,5-undecane, etc. The polymeric phenol-type antioxidants include 1,1,3-tris (2-methyl-4-hydroxy-5-tert-butylphenyl)butane, 1,3,5-trim ethyl-2,4,6-tris(3,5-di-tert-butyl-4-hydroxybenzyl)benzene, tetrakis-methylene-3-(3′,5′-di-tert-butyl-4′-hydroxyphenyl) propionate methane, bis{(3,3′-bis-4′-hydroxy-3′-tert-butyl phenyl)butyric acid glucose ester, 1,3,5-tris(3′,5′-di-tert-butyl-4′-hydroxybenzyl)-s-triazine-2,4,6-(1H.3H,5H)trione, and triphenol (vitamin E).

Sulfur-containing antioxidants include dilauroylthiodipropionate, dimyristylthiodipropionate, and distearylthiopropionate.

Phosphite-type antioxidants include triphenyl phosphite, diphenylisodecyl phosphite, phenyldiisodecyl phosphite, 4,4′-butylidene-bis(3-methyl-6-tert-butylphenyl-di tridecyl)phosphite, cyclic neopentane-tetrayl bis(octadecyl) phosphite, tris(mono and/or di)phenyl phosphite, diisodecyl pentaerythritol diphosphite, 9,10-dihydro-9-Oxa-10-phosphaphenanthrene-10-oxide, 10-(3,5-di-tert-butyl-4-hydroxybenzyl)-9,10-dihydro-9-Oxa-10-phosphaphenanthrene-10 oxide, 10-decyloxy-9,10-dihydro-9-Oxa-10 phosphaphenanthrene, cyclic neopentane-tetrayl bis(2,4-di tert-butylphenyl)phosphite, cyclic neopentane-tetrayl bis(2. 6-di-tert-methylphenyl)phosphite, and 2.2-methylenebis(4,6-tert-butylphenyl)octyl phosphite.

In one or more embodiments, antioxidants of the phenol-type and phosphite-type may be used alone, or preferably in combination to increase thermal stability.

The amount of the antioxidant to be added may be in an amount ranging from a lower limit of 0.001, 0.01, 0.1, 0.2, 0.3, 0.4, 0.5, 1, or 2 to 0.5, 0.6, 0.7, 0.8, 0.9, 1, 2, 3, 4, or 5 parts per hundred rubber/resin (phr) relative to 100 phr of the polymer, where any lower limit may be combined with any suitable upper limit. In one or more embodiments the antioxidant may be in an amount ranging from 0.01 to 0.5 phr.

### Light Stabilizer

The use of light stabilizers (LS) (especially hindered amine-type (HALS)) leads to a noticeable synergistic effect when combined with a UV-absorbent. Other LS typical compounds may function well playing the same role as the HALS, but many of them create color in the polymeric compound, and are therefore unfavorable for use in the solar cell encapsulant material. The hindered amine-type light stabilizers generally are secondary, tertiary, acetylated, N-hydrocarbyloxy substituted, hydroxy substituted, or other substituted cyclic amines with a considerable amount of steric hindrance. Specifically, it includes molecules such as dimethyl succinate-1-(2-hydroxyethyl)-4-hydroxy-2.2.6,6-tetramethyl piperidine polycondensate, poly(6-(1,1,3,3-tetramethylbutyl)amino-1,3,5-triazine-2,4-diy1}{(2.2.6.6-tetramethyl-4-piperidyl)iminohexamethylene{{2.2.6,6-tetramethyl-4-piperidylimino, N,N′-bis(3-aminopropyl) ethylenediamine-2,4-bis(N-butyl-N-(1.2.2.6,6-pentamethyl-4-piperidyl)amino-6-chloro-1,3,5-triazine condensate, bis (2.2.6,6-tetramethyl-4-piperidyl)sebacate, bis(1.2.2.6,6-pentamethyl-4-piperidyl)2-(3,5-di-tert-4-hydroxybenzyl)-2-n-butylmalonate, propandioic acid, C4-(methoxyphenyl)-methylene-, bis (1,2,2,6,6-pentamethyl-4-piperidinyl) ester, polymethylpropyl-3-oxy-4-(2,2,6,6-tetramethyl)piperidinylsiloxane, 3-Dodecyl-1-(2,2,6,6-tetramethyl-4-piperidinyl)-2,5-pyrrolidinedione, 1,3,5-Triazine-2,4,6-triamine,N,N′-1,2-ethanediylbis 4,6-bis butyl(1,2,2,6,6-pentamethyl-4-piperidiny) amino-1,3,5-triazine-2-yl)imino-3,1 propanediyl)-bisN′,N′-dibutyl-N′,N′-bis(1,2,2,6,6-pentamethyl-4-piperidinyl)-(Chimassorb 119, CAS Reg. No. 106990-43-6); N,N′-bis(2,2,6,6-Tetramethyl-4-piperidinyl)-1,6-hexane diamine, polymer with 2,4,6-trichloro-1,3,5-triazine and 2,4,4-trimethyl-1,2-pentamine (Chimassorb 944, ACS Reg. No. 70624-18-9); and N,N′-bis (2,2,6,6-Tetramethyl-4-piperidinyl)-1,6-hexane diamine polymer with 2,4,6-trichloro-1,3,5-triazine and tetrahydro 1,4-oxazine.

The amount of the light stabilizer may be in an amount ranging from a lower limit of 0.001, 0.01, or 0.1 to an upper limit ranging from 0.2, 0.3, 0.4, or 0.5 phr relative to 100 phr of the polymer, where any lower limit may be used in combination with any suitable upper limit. In one or more embodiments, the light stabilizer may be in an amount ranging from 0.01 to 0.3 phr.

### UV Absorbers

Any known UV absorber may find utility within the present disclosure. General classes of UV absorbers that are preferred are benzophenone, benzotriazoles, triazine, salicylate, hydroxybenzophenones, hydroxyphenyl triazines, esters of substituted and unsubstituted benzoic acids, and the like and mixtures thereof.

Specific benzophenone UV absorbents include, for example, 2-hydroxy-4-methoxybenzophe none, 2-hydroxy-4-methoxy-2-carboxybenzophenone, 2-hydroxy-4-Octoxybenzophenone, 2-hydroxy-4-n-dodecy loxybenzophenone, 2-hydroxy-4-n-octadecyloxybenzophe none, 2-hydroxy-4-benzyloxybenzophenone, 2-hydroxy-4-methoxy-5-sulfobenzophenone, 2-hydroxy-5-chlorobenzophenone, 2,4-dihydroxybenzophenone, 2,2′-dihydroxy-4-methoxybenzophenone, 2,2′-dihydroxy-4,4′-dimethoxybenzophenone, and 2,2′,4,4′-tetrahydroxybenzophenone.

The benzotriazole UV absorbents include hydroxy phenyl-substituted benzotriazole compounds, for example, 2-(2-hydroxy-5-methylphenyl)benzotriazole, 2-(2-hydroxy 5-t-butylphenyl)benzotriazole, 2-(2-hydroxy-3,5-dimethyl phenyl)benzotriazole, 2-(2-methyl-4-hydroxyphenyl)benzo triazole, 2-(2-hydroxy-3-methyl-5-t-butylphenyl) benzotriazole, 2-(2-hydroxy-3,5-di-t-amylphenyl) benzotriazole, and 2-(2-hydroxy-3,5-di-t-butylphenyl) benzotriazole.

The triazine UV absorbents include 2-4,6-bis(2,4-dimethylphenyl)-1,3,5-triazin-2-yl)-5-(octyloxy)phenol, 2-(4,6-diphenyl-1,3,5-triazin-2-yl)-5-(hexyloxy)phenol, etc. The salicylate-type UV absorbents include phenyl salicylate, and p-octylphenyl salicylate.

The amount of the UV absorbent may be in an amount ranging from a lower limit of 0.001, 0.01, 0.1, 0.2, 0.3, 0.4, or 0.5 to an upper limit of 0.5, 1.0, 2.0, 3.0, 4.0, or 5.0 parts per hundred rubber/resin (phr) relative to 100 phr of the polymer, where any lower limit may be used in combination with any suitable upper limit. In one or more embodiments the UV absorbent may be in an amount ranging from 0.01 to 0.5 phr.

### Adhesion Promoters

The most used adhesion promoter are silane coupling agents, which are effective for improving adhesive strength of the encapsulant material to a protective material (front sheet, back sheet and others made of glass or polymers) and to solar cell elements, such as the photovoltaic device, metallic grids, and others. Compounds containing unsaturations (e.g. vinyl group), an acryloxy group or a methacryloxy group, an amino group, an epoxy group or the like, and additionally having a hydrolysable group such as an alkoxy group, are feasible molecules for coupling agents.

Some specific molecules that fit the aforementioned categories are γ-chloropropylmethoxysilane, vinyltrimethoxysilane, vinyltriethoxysilane, vinyltris(ß-methoxyethoxy)silane, γ-vinylbenzylpropyltrimethoxysilane, N-ß-(N-vinylbenzylaminoethyl)-γ-aminopropyltrimethoxysilane, vinyltriacetoxysilane, γ-glycidoxypropyltriethoxysilane, ß-(3.4-epoxycyclohexyl)ethyltrimethoxysilane, vinyltrichlorosilane, γ-mercaptopropylmethoxysilane, γ-aminopropyltriethoxysilane, N-ß-(aminoethyl)-γ-aminopropyltrimethoxysilane, N-(3-aminoethyl)-γ-aminopropyltrimethoxysilane, N-(3-aminoethyl)-y-aminopropylmethyldimethoxysilane, γ-aminopropyltriethoxysilane, γ-glycidoxypropyltrimethoxysilane, γ-methacryloxypropyltrimethoxysilane, etc., where the last two are the best options for the present application, since they lead to good adhesiveness and cause little color issues upon grafting/reaction, such as yellowing.

The amount of the silane coupling agent may be in an amount ranging from a lower limit of 0.01, 0.05, 0.1, 0.5, or 1 to an upper limit ranging from 1, 2, 3, 4, or 5 phr relative to 100 phr of polymer, where any lower limit may be used in combination with any suitable upper limit. In one or more embodiments, the silane coupling agent may be in an amount ranging from 0.1 to 3 phr.

### Thermal Stabilizer

Thermal stabilizers can be used in solar cell encapsulants, as an optional additive, in order to protect the polymer especially during processing, especially during the curing stage. Any regular thermal stabilizer may be used, which include but are not limited to: phenolic antioxidants, alkylated monophenols, alkylthiomethylphenols, hydroquinones, alkylated hydroquinones, tocopherols, hydroxylated thiodiphenyl ethers, alkylidenebisphenols, O-, N- and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid (vitamin C), peroxide deactivators, hydroxylamines, nitrones, thiosynergists, benzofuranones, indolinones, and mixtures thereof. Its use is optional and in some instances is not preferred (especially if it severely suppresses crosslinking).

The thermal stabilizer may be in an amount ranging from a lower limit of 0.001, 0.01, 0.1, or 0.2 to an upper limit ranging from 1, 2, 3, 4, or 5 phr relative to 100 phr of the polymer, where any lower limit may be used in combination with any suitable upper limit. In one or more embodiments, the thermal stabilizer may be in an amount ranging from 0.01 to 1 phr.

### Plasticizers

Polymer compositions in accordance with the present disclosure may contain one or more plasticizers to adjust the physical properties and processability of the composition. In some embodiments, plasticizers in accordance with the present disclosure may include one or more of bis(2-ethylhexyl) phthalate (DEHP), di-isononyl phthalate (DINP), bis (n-butyl) phthalate (DNBP), butyl benzyl phthalate (BZP), di-isodecyl phthalate (DIDP), di-n-octyl phthalate (DOP or DNOP), di-o-octyl phthalate (DIOP), diethyl phthalate (DEP), di-isobutyl phthalate (DIBP), di-n-hexyl phthalate, tri-methyl trimellitate (TMTM), tri-(2-ethylhexyl) trimellitate (TEHTM-MG), tri-(n-octyl, n-decyl) trimellitate, tri-(heptyl, nonyl) trimellitate, n-octyl trimellitate, bis (2-ethylhexyl) adipate (DEHA), dimethyl adipate (DMD), mono-methyl adipate (MMAD), dioctyl adipate (DOA)), dibutyl sebacate (DBS), polyesters of adipic acid such as VIERNOL, dibutyl maleate (DBM), di-isobutyl maleate (DIBM), benzoates, epoxidized soybean oils and derivatives, n-ethyl toluene sulfonamide, n-(2-hydroxypropyl) benzene sulfonamide, n-(n-butyl) benzene sulfonamide, tricresyl phosphate (TCP), tributyl phosphate (TBP), glycols/polyesters, triethylene glycol dihexanoate, 3gh), tetraethylene glycol di-heptanoate, polybutene, acetylated monoglycerides; alkyl citrates, triethyl citrate (TEC), acetyl triethyl citrate, tributyl citrate, acetyl tributyl citrate, trioctyl citrate, acetyl trioctyl citrate, trihexyl citrate, acetyl trihexyl citrate, butyryl trihexyl citrate, trihexyl o-butyryl citrate, trimethyl citrate, alkyl sulfonic acid phenyl ester, 2-cyclohexane dicarboxylic acid di-isononyl ester, nitroglycerin, butanetriol trinitrate, dinitrotoluene, trimethylolethane trinitrate , diethylene glycol dinitrate, triethylene glycol dinitrate, bis (2,2-dinitropropyl) formal, bis (2,2-dinitropropyl) acetal, 2,2,2-trinitroethyl 2-nitroxyethyl ether, mineral oils, vegetable or biobased oil, among other plasticizers and polymeric plasticizers. In particular embodiments, one of the one or more plasticizers may be mineral oil.

Polymer compositions in accordance with the present disclosure may optionally include plasticizers in an amount ranging from 0 to 20 phr. The plasticizer may be present in an amount ranging from a lower limit of one of 0 phr, 1.0 phr, 2.0 phr, and 5.0 phr, 8.0 phr and 10.0 phr, to an upper limit of one of 12 phr, 15 phr, 18 phr, 19 phr, and 20 phr where any lower limit may be combined with any suitable upper limit.

### Films

In one or more embodiments, films may be prepared which comprise the polymer composition described above and specifically including the co- or ter-polymers. Films may be prepared by cast film extrusion, blown film extrusion, calendaring, or any method which is suitable for preparing a film. Films according to the present disclosure may be suitable for use as solar cell encapsulants, tie layers, and glass lamination. The films may be either un-crosslinked or crosslinked.

Films according to one or more embodiments may comprise a polymer (the co- or ter-polymer) having a total commoner content (branched vinyl ester and optional vinyl acetate) that ranges from a lower limit selected from one of 5 wt %, 10 wt %, 15 wt %, 20 wt %, 25 wt %, or 30 wt % to an upper limit selected from 30 wt %, 35 wt %, 40 wt %, 45 wt %, 50 wt %, 55 wt %, or 60 wt % where any lower limit may be combined with any suitable upper limit.

Films according to one or more embodiments may comprise a polymer (the co- or ter-polymer) having a density that ranges from a lower limit selected from one of 0.8 g/cm³, 0.9 g/cm³, 0.905 g/cm³, 0.91 g/cm³, 0.915 g/cm³, 0.92 g/cm³, 0.925 g/cm³, 0.93 g/cm³, to an upper limit selected from one of 0.95 g/cm³, 0.955 g/cm³, 0.96 g/cm³, 0.965 g/cm³, 0.97 g/cm³, 0.98 g/cm³, 0.99 g/cm³, 1.0 g/cm 3 , 1.1 g/cm³, 1.2 g/cm³, or 1.3 g/cm³ where any lower limit may be combined with any suitable upper limit.

Films according to one or more embodiments may comprise a polymer (the co- or ter-polymer) having a melt index (I₂) measured according to ASTM D1238 (190° C. and a load of 2.16 kg) ranging from a lower limit of 0.1 g/10 min, 0.5 g/10 min, 1 g/10 min, 2 g/10 min, 5 g/10 min, 10 g/10 min, 15 g/10 min, 20 g/10 min, 30 g/10 min, 40 g/10 min, or 50 g/10 min to an upper limit of 50 g/10 min, 60 g/10 min, 70 g/10 min, 80 g/10 min, 90 g/10 min, or 100 g/10 min where any lower limit may be combined with any suitable upper limit.

Films according to one or more embodiments may have a thickness ranging from a lower limit of 0.1 μm, 0.5 μm, 1 μm, 2 μm, 3 μm, 4 μm, 5 μm, 10 μm, 15 μm, 20 μm, 30 μm, 50 μm, 100 μm, 200 μm, 300 μm, 400 μm, or 500 μm, to an upper limit of 500 μm, 600 μm, 700 μm, 800 μm, 900 μm, or 1000 μm where any lower limit may be combined with any suitable upper limit.

### Solar Cell Encapsulant

As mentioned above, the films of the present disclosure may be used as a solar cell encapsulant, in which the film may be applied onto a solar or photovoltaic (PV) cell as a substrate.

PV cells may be crystalline, semi-crystalline, or amorphous, and they are generally packaged in multiple protective layers including a front cover, an encapsulant film, and a back sheet, for example, as a five-layer laminate of front cover/encapsulant film/PV cell and electrical wiring/encapsulant film/back sheet. The polymer composition and film containing the polymer composition of the present disclosure may be used as the encapsulant in particular.

Films for use as a solar cell encapsulant may include, in addition to the co- or ter-polymer described herein, one or more of: a crosslinking agent in an amount of 0.01 to 10 phr; a crosslinking coagent in an amount of 0.01 to 5 phr; a primary antioxidant in an amount of 0.01 to 5 phr; a secondary antioxidant in an amount of 0.01 to 5 phr; a light stabilizer in an amount of 0.01 to 5 phr; an UV absorber in an amount of 0.01 to 5 phr; an adhesion promoter in an amount of 0.01 to 5 phr; or optionally, at least one additive selected from the group consisting of thermal stabilizers, plasticizers, rubbers, elastomers, fillers, and combinations thereof.

In one or more embodiments, films suitable for use as a solar cell encapsulant may comprise a polymer having a density that ranges from a lower limit selected from one of 0.92 g/cm³, 0.925 g/cm³, 0.93 g/cm³, 0.935 g/cm³, or 0.94 g/cm³ to an upper limit selected from one of 0.95 g/cm³, 0.955 g/cm³, 0.96 g/cm³, 0.965 g/cm³, or 0.97 g/cm³, where any lower limit may be combined with any suitable upper limit. In one or more embodiments, the polymer may have a density ranging from 0.93 g/cm³ to 0.96 g/cm³.

In one or more embodiments, films suitable for use as a solar cell encapsulant may comprise a polymer having a melt index (I₂) measured according to ASTM D1238 (190° C. and a load of 2.16 kg) ranging from a lower limit of 1 g/10 min, 2 g/10 min, 5 g/10 min, 10 g/10 min, 15 g/10 min, 20 g/10 min, 25 g/10 min, 30 g/10 min, 40 g/10 min, or 50 g/10 min to an upper limit of 50 g/10 min, 60 g/10 min, 70 g/10 min, 80 g/10 min, 90 g/10 min, 100 g/10 min, 150 g/10 min, or 200 g/10 min where any lower limit may be combined with any suitable upper limit. In one or more embodiments, the polymer may have a melt index (I₂) ranging from 2 g/10 min to 200 g/10 min, or even from 5 g/10 min to 50 g/10 min.

In one or more embodiments, films suitable for use as a solar cell encapsulant may comprise a polymer having a melting temperature measured according to ASTM D3418 ranging from a lower limit of 30° C., 40° C., 50° C., or 60° C. to an upper limit of 60° C., 70° C., 80° C., 90° C., or 100° C. where any lower limit may be combined with any suitable upper limit. In one or more embodiments, the polymer may have a melting temperature of less than 90° C. or ranging from 60° C. to 80° C.

In one or more embodiments, films suitable for use as a solar cell encapsulant may comprise a polymer having a volumetric electrical resistivity measured according to ASTM D257 of greater than 1×10¹⁴ Ohm·cm, or greater than 1×10¹⁵ Ohm·cm.

In one or more embodiments, films suitable for use as a solar cell encapsulant may comprise a polymer having a Shore A Hardness measured according to ASTM D2240 of less than 90 Shore A, or of less than 80 Shore A.

In one or more embodiments, films suitable for use as a solar cell encapsulant may comprise a polymer having a Vicat Softening Point measured according to ASTM D1525 of less than 75° C., or 70° C., or 65° C., or 60° C., or 55° C., or 50° C., or 45° C., or 42° C.

In one or more embodiments, films suitable for use as a solar cell encapsulant may comprise a polymer having a contact angle measured according to ASTM D5946 of greater than 70°, or 75°, or 80°, or 85°, or 90°.

In one or more embodiments, films suitable for use as a solar cell encapsulant may have an optical transmittance measured according to ASTM D1003 of greater than 80%, or 85%, or 90%, or 91%, or 92%, or 93%, or 94%, or 95%.

In one or more embodiments, films suitable for use as a solar cell encapsulant may have a haze of less than 15%, or 10%, or 9%, or 8%, or 7%, or 6%, or 5%.

In one or more embodiments, films suitable for use as a solar cell encapsulant may have a water vapor transmission coefficient measured according to ASTM F1249 of less than 25000 μm·g/m²·day, 24000 μm·g/m²·day, 23000 μm·g/m²·day, 22000 μm·g/m²·day, 21000 μm·g/m²·day, or 20000 μm·g/m²·day.

In one or more embodiments, films suitable for use as a solar cell encapsulant may have a stress at break measured according to ASTM D638 of at least 5 MPa, 6 MPa, 7 MPa, 8 MPa, 9 MPa, or 10 MPa.

In one or more embodiments, films suitable for use as a solar cell encapsulant may have a strain at break measured according to ASTM D638 of at least 500%, 600%, 700%, 800%, 900%, or 1000%.

In one or more embodiments, films suitable for use as a solar cell encapsulant is crosslinked and may have a UV cut-off wavelength of 380 nm, or even of 360 nm, as measured by UV/Vis or UV/Vis/NIR spectroscopy.

In one or more embodiments, films suitable for use as a solar cell encapsulant may exhibit a gloss at 45° measured according to ASTM D2457 of at least 70%, 73%, 77%, or 80%.

In one or more embodiments, films suitable for use as a solar cell encapsulant may exhibit a gloss at 60° measured according to ASTM D2457 of at least 80%, 85%, 90%, or 95%.

In one or more embodiments, films suitable for use as a solar cell encapsulant may comprise a polymer composition which exhibits a glass transition temperature measured via tan δ of less than −15° C., −17° C., −19° C., −21° C., −23° C., or −25° C.

In one or more embodiments, films suitable for use as a solar cell encapsulant may comprise a polymer composition which exhibits a glass transition temperature measured via loss modulus of less than −25° C., −27° C., −29° C., −31° C., −33° C., or −35° C.

### Methods of Film Preparation

Embodiments disclosed herein may relate to methods of preparing films which comprise a polymer composition according to the present disclosure. Methods may comprise preparing a polymer composition by blending a polymer produced from ethylene, one or more branched vinyl ester monomers, and optionally, vinyl acetate according to embodiments described herein, and optionally one or more of each of a peroxide; a crosslinking coagent; a primary antioxidant; a secondary antioxidant; a light stabilizer; an UV absorber; an adhesion promoter, and thermal stabilizers, plasticizers, rubbers/elastomers, fillers, and combinations thereof.

Blending may be performed according to any suitable method, and may comprise using a twin screw extruder, single screw extruder, kneader, banbury mixer, mixing roller, or a cast film extruder.

The prepared polymer composition may then be used to prepare a film comprising the polymer composition. The film may be produced via cast film extrusion, blown film extrusion, calendaring, or any other suitable method.

### Articles

Embodiments disclosed herein may relate to articles comprising at least one film disclosed herein. The article may comprise a substrate to which the film is applied. The article may comprise one or more than one substrate. For example, the article may be an encapsulated solar cell.

### Method of Preparing an Article

Embodiments disclosed herein may relate to methods of preparing articles comprising films according to embodiments disclosed herein. Methods may include applying a film to a substrate, wherein the applying comprises vacuum laminating a film according to the present disclosure to a substrate, wherein the film encapsulates and/or bonds a photovoltaic device to the substrate. Encapsulation of a photovoltaic device may comprise crosslinking a film according to the present disclosure via exposure to a vacuum lamination process.

The vacuum lamination process may be performed at a pressure ranging from a lower limit of 5 kPa, 10 kPa, 20 kPa, 30 kPa, 40 kPa, or 50 kPa to an upper limit of 100 kPa, 150 kPa, or 200 kPa where any lower limit may be combined with any suitable upper limit.

The vacuum lamination process may be performed at a temperature ranging from a lower limit of 50° C., 60° C., 70° C., 80° C., 90° C., 100° C., 110° C., 120° C., 130° C., 140° C., 150° C., 160° C., 170° C., 180° C., or 190° C. to an upper limit of 190° C., 200° C., 210° C., 220° C., 230° C., 240° C., 250° C., 260° C., 270° C., 280° C., 290° C., 300° C., 310° C., or 320° C. where any lower limit may be combined with any suitable upper limit.

The vacuum lamination process may be performed for a time frame ranging from a lower limit of 0.5 min, 1 min, 2 min, 3 min, 4 min, 5 min, 10 min, 20 min, 30 min to an upper limit of 60 min, 75 min, 90 min, or 2 hours where any lower limit may be combined with any suitable upper limit.

### Materials, Experimental Methods and Characterization

### Materials

Compositions based on ethylene, vinyl acetate and vinyl neodecanoate (VeoVA™10) were tested. Terpolymer samples DV001A and DV001B were produced in a high-pressure industrial asset that normally operates producing EVA copolymers. The general reactor conditions for the production of the terpolymers are described in Table 1.

TABLE 1

| Parameter | DV001A | DV001B |
|---|---|---|
| Pressure-reactor 1 (kgf/cm²) | 1820-1840 | 1820-1840 |
| Temperature-reactor 1 (average) (° C.) | 164.5 | 164.5 |
| Pressure-reactor 2 (kgf/cm²) | 1780-1800 | 1770-1790 |
| Temperature-reactor 2 (average) (° C.) | 161.7 | 163.7 |
| Production rate (kg/h)* | 6000 | 6000 |
| VA feed rate (kg/h) | 2850-3200 | 2400 |
| Ethylene feed rate (kg/h) | 4270 | 4300 |
| VeoVA ™10 feed rate (kg/h) | 800-900 | 1650 |

*Difference in feed rate sum and production rate due to condensation of the comonomers and their low pressure recycle gas/liquid compressor separator.
The condensed VeoVA ™10 was not reinjected.
Part of unreacted VeoVA ™10 remains soluble in the polymer, being removed in a further step of air purge at the silos.

Evidence of incorporation of the branched vinyl ester and vinyl acetate is seen in both the carbonyl (170-180 ppm) and alkyl regions (0-50 ppm) of the ¹³C NMR spectra (TCE-D2, 393.1 K, 125 MHz). ¹H NMR spectra (TCE-D2, 393.2 K, 500 MHz) exhibit peaks for vinyl acetate and branched vinyl ester (4.7-5.2 ppm) and ethylene (1.2-1.5 ppm) as well as additional peaks in the alkyl region (0.5-1.5 ppm) indicative of the long alkyl chains on the branched vinyl ester monomers. Relative intensity of the peaks found in ¹H NMR and ¹³C NMR spectra are used to calculate monomer incorporation of branched vinyl ester and vinyl acetate in the co-/terpolymers.

### Neat Polymer Characterization

The content of VA and VeoVa™10 were measured by ¹H NMR and ¹³C NMR, as described above. Melting and crystallization behavior of the samples were studied by DSC. The experiments were carried out in a TA Instruments DSC Discovery—DSC 2500, under nitrogen according to ASTM D3418. Samples were cooled down from 200 to −20° C. and subsequently heated up to 200° C. with a rate of 10° C./min.

The density was measured according to ASTM D792, Vicat softening point (10N) according to ASTM D1525, Hardness (Shore A) according to ASTM D2240, contact angle following ASTM D5946 and volumetric electrical resistivity was measured according to ASTM D257. The specimens for the measurements of density, Vicat, Hardness, contact angle and volumetric electrical resistivity were prepared by compression molding according to ASTM D4703, with a conditioning of at least 24 hours at 23° C., 50% RH. Melt flow rate was evaluated at 190° C., 2.16 kg, following ASTM D1239.

### Neat and Compound Film Extrusion

Cast films of the aforementioned polymers (neat) and of the compounds that will be described in Example 3 were produced in a cast film extruder Leonard OCS ME-20/2800-V3, with a flat die, chilled pulling rolls. Prior the extrusions the die was cleaned with the aid of a spatula and a brass wool. The temperature profile and melt temperature were limited to 140° C. (lower than 120° C. for formulations) in order to evaluate processability and aesthetics of the films under these conditions. Because of the strong adhesion of EVA films to the pinch rolls, they were previously covered with brown paper and chilled to approximately 9° C.

### Film Characterization

Relevant properties (optical, mechanical and barrier) were tested in neat films of the polymers, and they are exhibited in the tables below. Water vapor transmission rate and crosslinking degree by gel content in boiling xylene could also be measured in the crosslinked film (description in Example 4).

Optical properties (clarity, haze and transmittance) were measured as determined by ASTM D1003, gloss (45 and 60°) according to ASTM D2457, water vapor transmission rate was measured according to ASTM F1249 (37.8° C., 100 RH, 1 atm), and tensile testing was performed according to ASTM D882 (crosshead speed of 500 mm/min, using an optic extensometer, where stress and strain at yield and break, and secant modulus (1%) were reported.

### Compression Molded Samples—Crosslinking Protocol

Samples were crosslinked via compression mold (standard heating cycle, followed by 1 hour at 150° C. at standard pressure, followed by a standard cooling cycle, according to ASTM D4703.

### Crosslinked Compression Molded Samples Characterization

Crosslinked compression molded samples were tested for tensile (stress and strain at break, and tensile modulus—measured at 500 mm/min, using an optical extensometer, according to ASTM D638), Shore A hardness (according to ASTM D2240), DSC (according to ASTM D3418, test from −20 to 200° C., heating rate of 10° C./min), gel content (internal method based on ASTM D2765—sieve of mesh #120, boiling xylene extraction, 8 h, followed by drying in oven at 100-150° C., until constant weight is achieved (˜1 hour)), and DMA (tensile mode, from −150 to 150° C., with a heating rate of 3° C./min, amplitude of deformation 15 microns).

Glass transition temperature (T_{g}) for both neat and crosslinked samples were determined from the measurement of Tan δ peak maximum of the samples during DMA measurements using a TA 800 DMA instrument in the tensile mode. Films (˜0.5 mm) were compression molded at 150° C., cooled to −150° C. and their viscoelastic response were evaluated through temperature sweep with a rate of 3° C./min while a preload force of 0.01 N with a frequency of 1 Hz and amplitude of 15 μm was applied. Storage modulus, loss modulus, and tan 6 (ratio of storage to loss modulus) was recorded as a function of temperature.

### EXAMPLES

Example 1: Neat polymer characterization—The basic properties of the aforementioned terpolymers (labeled DV001A, DV001B), as well as EVA benchmarks—Braskem S.A. grade HM728 and SK Chemicals Co. grade EVATANE 3345PV—are displayed in Table 2.

TABLE 2

| | | | | | EVATANE |
|---|---|---|---|---|---|
| Property | | DV001A | DV001B | HM728 | 3345PV |
| VA Content | Wt % | 28.3 | 24.1 | 28* | 33* |
| VeoVA ™10 | Wt % | 5.6 | 9.3 | — | — |
| content | | | | | |
| MFR | g/10 min | 6.9 | 5.2 | 5.9 | 35.7 |
| 190° C./ | | | | | |
| 2.16 Kg | | | | | |
| Density | g/cm³ | 0.947 | 0.943 | 0.950* | 0.956 |
| (Liquid | | | | | |
| displacement) | | | | | |
| Vicat | @ 10 N | 40.1 | 41.4 | 42 | 29 |
| | (° C.) | | | | |
| Hardness | Shore A | 75.2 | 77.6 | 81.1 | 71.9 |
| Contact angle | ° | 86.6 | 80.3 | 83.7 | 94.4 |

*Data from technical datasheet.

Volumetric electrical resistivity was measured according to ASTM D257 in compression molded neat parts (thickness 2 mm) according to ASTM D4703. Results are displayed in Table 3.

TABLE 3

| | Volumetric electrical | Standard |
|---|---|---|
| Sample | resistivity (Ohm · cm) | deviation |
| DV001A | 2.74 × 10¹⁵ | 3.89 × 10¹⁴ |
| DV001B | 3.72 × 10¹⁵ | 1.49 × 10¹⁵ |
| HM728 | 3.04 × 10¹⁵ | 7.29 × 10¹⁴ |
| EVATANE | 6.70 × 10¹⁴ | 7.60 × 10¹³ |
| 3345PV | | |

Volumetric electrical resistivity for the terpolymers display very close values compared to HM728, with the average value of DV001B slightly higher. The three aforementioned grades present resistivity considerably higher than EVATANE 3345PV. High volumetric electrical resistivity values are desirable for such application, as current escape or dielectric rupture are extremely undesirable, since it diminishes module efficiency or even disrupts its function.

Example 2: Neat films were prepared according to the film extrusion protocol described above. The films were collected and rolled with a brown paper in order to avoid blocking. The extrusion parameters were as follows:

TABLE 4

| | EVATANE | | | |
|---|---|---|---|---|
| Sample | 3345PV | HM728 | DV001A | DV001B |
| Zone 1 T (° C.) | 54 | 100 | 100 | 100 |
| Zone 2 T (° C.) | 70 | 130 | 130 | 130 |
| Zone 4 T (° C.) | 90 | 130 | 130 | 130 |
| Zone 4 T (° C.) | 90 | 135 | 135 | 135 |
| Head T (° C.) | 102 | 135 | 135 | 135 |
| Die T 1 (° C.) | 101 | 135 | 135 | 135 |
| Die T 2 (° C.) | 107 | 135 | 135 | 135 |
| Melt temperature | 104 | 138 | 139 | 140 |
| (° C.) | | | | |
| Target thickness (μm) | ~480 (center) | 451 | 493 | 487 |
| | ~550 (edges) | | | |
| Melt pressure (bar) | 100 | 224 | 189 | 193 |
| Screw speed (rpm) | 110 | 100 | 108 | 108 |
| Roll temperature (° C.) | 10 | 10 | 8.7 | 8.7 |
| Motor torque (A) | 3 | 3 | 3 | 3 |
| Pulling speed (m/min) | 3.7 | 3.7 | 3.7 | 3.7 |

Films were characterized according to the methods described above. Overall, similar optical properties are observed; with a slightly higher clarity and lower haze for the terpolymers compared to HM728, as shown in Tables 5 and 6. Evatane displayed better optical properties, however, the extrusion was also facilitated because of the higher MFR, which heavily affects optical properties. Lower water vapor transmission coefficient was observed for the terpolymers, especially for DV001B , which contains the most VeoVa™10 monomer, as shown in Table 7.

TABLE 5

| | | | | | | Film |
|---|---|---|---|---|---|---|
| | | Gloss | Gloss | | Transmittance | thickness |
| Sample | Clarity (%) | (45°) (%) | (60°) (%) | Haze (%) | (%) | (μm) |
| DV001A | 91.8 ± 1.6 | 77.9 ± 2.4 | 100 | 5.1 ± 1 | 93.8 ± 0.1 | 493 |
| DV001B | 94.3 ± 0.6 | 77 ± 3 | 100 | 5.1 ± 1.5 | 93.8 ± 0.1 | 487 |
| HM728 | 89.7 ± 1 | 77.9 ± 3.6 | 100 | 7.7 ± 1.8 | 93.9 ± 0.1 | 451 |
| EVATANE | 98.4 ± 0.2 | 86.2 ± 3.6 | 100 | 3.6 ± 1.6 | 94 ± 0.2 | 480 |
| 3345PV | | | | | | |

TABLE 6

| | Tensile Secant Modulus | Yield Strength | Strain at Yield | Stress at break | Strain at Break |
|---|---|---|---|---|---|
| Sample | (1%) (MPa) | (MPa) | (%) | (MPa) | (%) |
| DV001A | 15 ± 0.4 | 2.1 ± 0 | 21.1 ± 0.3 | 10.3 ± 0.2 | 890 ± 43 |
| DV001B | 16 ± 0.4 | 2 ± 0.1 | 19.1 ± 0.8 | 9.7 ± 0.7 | 850 ± 54 |
| HM728 | 20 ± 0.7 | 2.7 ± 0.1 | 23.4 ± 1 | 14.6 ± 0.5 | 940 ± 54 |
| EVATANE | 9 ± 0.2 | 1.5 ± 0.0 | 30.8 ± 1.7 | 8.1 ± 0.3 | 1440 ± 69 |
| 3345PV | | | | | |

TABLE 7

| | Water Vapor | Water Vapor | Film |
|---|---|---|---|
| | Transmission Rate | Transmission Coefficient | thickness |
| Sample | (g/m² · day) | (μm · g/m² · day) | (μm) |
| DV001A | 27.2 | 13400 | 493 |
| DV001B | 22.5 | 10900 | 487 |
| HM728 | 28.4 | 13800 | 485 |
| EVATANE | 44.2 | 20700 | 468 |
| 3345PV | | | |

Example 3: The following formulation was compounded for all the previously described materials in a twin-screw extruder ZSK-26, by Coperion, with cooling of the strand in a water bath, followed by pelletizing. The sample preparation consisted of micronizing (cryogenic conditions—Liquid N2) ˜20% wt of the EVA in order to better absorb the liquid peroxide, followed by dry blending all components in a plastic bag, as shown in Table 8, finally feeding the main feeder of the extruder with the specified extrusion conditions, as shown in Table 9.

TABLE 8

| Component | Base formulation (phr) |
|---|---|
| Polymer | 100 |
| Luperox 101 | 1.5 |
| AOx 1010 | 0.2 |
| UV Absorber | 0.3 |
| Light Stabilizer | 0.1 |

Light stabilizer - Chimassorb 944 (HALS) - Poly[[6-[(1,1,3,3-tetramethylbutyl)amino]-1,3,5-triazine-2,4-diyl][(2,2,6,6-tetramethyl-4-piperidinyl)imino]-1,6-hexanediyl[(2,2,6,6-tetramethyl-4-piperidinyl)imino]])
UV Absorber - UV Absorver - Chimassorb 81 (Benzophenone) - 2-Hydroxy-4-octoxybenzophenone
Antioxidant - AOx 1010 - Sterically hindered phenolic primary antioxidant - pentaerythritol tetrakis[3-[3,5-di-tert-butyl-4-hydroxyphenyl]propionate
Luperox 101 - 2,5-dimethyl-2,5-di-(tert-butylperoxy)hexane

TABLE 9

| | | | | EVATANE |
|---|---|---|---|---|
| Polymer | HM728 | DV001A | DV001B | 3345 PV |
| Temperature | 40 - 60 - 90 - 90 - 100 - 100 - 110 - 110 - 110 - 120 | | | |
| profile (° C.) | | | | |
| Melt temperature | 123 | 122 | 121 | 107 |
| (° C.) | | | | |
| Screw speed | 150 | | | |
| (rpm) | | | | |
| Throughput rate | 10 | | | |
| (kg/h) | | | | |
| Pressure (bar) | 35 | 24 | 34 | 16 |
| Torque (%) | 32 | 32 | 30 | 32 |

| | |
|---|---|
| Screw design | One melting/mixture section, with 45° kneading blocks |

Samples were crosslinked and characterized according to methods described above. Despite differences in thickness compared to compression molded plates, the crosslinked materials presented a significant increase in stress at break compared to the neat polymers.

TABLE 10

| | | Tensile Secant | Stress at | Strain at |
|---|---|---|---|---|
| | Hardness | Modulus | break | Break |
| Sample | (Shore A) | (1%) (MPa) | (MPa) | (%) |
| DV001A | 77.2 ± 0.4 | 3.4 ± 1.3 | 20.2 ± 1.8 | 1860 ± 58 |
| DV001B | 78.1 ± 0.7 | 3.3 ± 0.5 | 19.5 ± 2.2 | 1830 ± 66 |
| HM728 | 80.7 ± 0.5 | 4.5 ± 2.5 | 24.9 ± 1.6 | 1800 ± 42 |
| EVATANE | 72.4 ± 0.2 | 3.1 ± 0.5 | 22.7 ± 1.9 | 1980 ± 42 |
| 3345PV | | | | |

The glass transition temperature was obtained for both neat and crosslinked films prepared according to the methods described above. The results are as follows:

TABLE 11

| | Tg (° C.) | Tg (° C.) |
|---|---|---|
| Sample | (Tan δ) | (Loss Modulus) |
| HM728 (Neat) | −19.9 | −29.3 |
| EVATANE 3345PV (Neat) | −22.6 | −30.2 |
| DV001A (Neat) | −21.4 | −32.8 |
| DV001B (Neat) | −21.6 | −33.1 |
| HM728 (Crosslinked) | −20.0 | −30.8 |
| EVATANE 3345PV (Crosslinked) | −22.8 | −32.0 |
| DV001A (Crosslinked) | −23.3 | −33.9 |
| DV001B (Crosslinked) | −23.6 | −34.3 |

It can be seen that the Tg of the terpolymers are very similar to each other, and they are comparable to the value measured for the 33 wt % VA EVA (EVATANE 3345PV) when neat (slightly higher via tan δ, and lower via loss modulus), and also when crosslinked (lower via tan δ and loss modulus). Also, both terpolymers presented a lower Tg than EVA with 28 wt % VA (HM728). This is an indication that the studied terpolymers present good low temperature flexibility, maybe even superior to commercial products.

When neat, EVATANE has a slightly lower Tg via tan δ and slightly higher peak, which mean higher segmental mobility (as it is a polymer with lower crystallinity), followed by the terpolymers (very similar to each other), and lastly, HM728, with slightly higher Tg and lower tan δ peak. A similar trend was observed for the crosslinked polymers; however, the crosslinked terpolymers present an even closer behavior to EVATANE 3345PV.

The gel content via boiling xylene extraction was determined according to the methodology previously described. The results are as follows:

TABLE 12

| Sample | Gel content (%) |
|---|---|
| DV001A | 96.3 |
| DV001B | 96.8 |
| HM728 | 97.4 |
| EVATANE 3345PV | 97.0 |

Thermal properties of neat and crosslinked samples were determined via DSC, according to the methodology previously described. Crosslinked samples were cut from the tensile test dog bones, and neat samples were molded into thin films. One can see the same trend for crosslinked samples as the neat polymers, with slightly lower Tm2, Tc and ΔHm (melting enthalpy) for DV001A compared to HM728, but with a pronounced Tc reduction for the terpolymer with 5 wt % of VeoVA™10, as shown in Table 13.

TABLE 13

| Sample | Tm2 (° C.) | Tc (° C.) | ΔHm (J/g) |
|---|---|---|---|
| HM728 (Neat) | 73.3 | 54.1 | 48.1 |
| EVATANE 3345PV (Neat) | 61.8 | 42.1 | 38.7 |
| DV001A (Neat) | 72 | 52.5 | 43.1 |
| DV001B (Neat) | 73.7 | 55.7 | 47.6 |
| HM728 (Crosslinked) | 66.0 | 45 | 42.7 |
| EVATANE 3345PV (Crosslinked) | 55.1 | 35 | 28.7 |
| DV001A (Crosslinked) | 64.1 | 33 | 38.8 |
| DV001B (Crosslinked) | 66.7 | 45 | 40.3 |

DSC data also follows, generally, the trends observed for the neat polymers, with much lower Tm and fusion enthalpy of EVATANE compared to the other materials. All materials presented lower Tm, Tc and ΔH when crosslinked possibly due to decreased crystallinity as well as lamellar thickness because of chain mobility constrictions imposed by the crosslinking).

DV001A presented lower Tm, Tc and ΔHm than HM728, which matches the results seen for optical properties, Hardness, modulus, tensile and Vicat. DV001B presented essentially the same thermal behavior as HM728, however, presented superior optical properties (yet slightly)—as seen in example 4.

Example 4: Films of the extruded formulations were produced via cast film extrusion, using the same methodology/considerations as for the neat films (except that no brown paper was used to cover the chill rolls). The extrusion parameters were as follows:

TABLE 14

| | EVATANE | | | |
|---|---|---|---|---|
| Sample | 3345PV | HM728 | DV001A | DV001B |
| Zone 1 T (° C.) | 55 | 72 | 60 | 60 |
| Zone 2 T (° C.) | 72 | 90 | 80 | 80 |
| Zone 4 T (° C.) | 92 | 99 | 91 | 91 |
| Zone 4 T (° C.) | 100 | 101 | 95 | 95 |
| Head T (° C.) | 102 | 105 | 106 | 105 |
| Die T 1 (° C.) | 100 | 102 | 101 | 100 |
| Die T 2 (° C.) | 106 | 108 | 105 | 105 |
| Melt temperature | 105 | 111 | 112 | 111 |
| (° C.) | | | | |
| Film thickness (μm) | ~420 | | ~350 | |
| | (center) | | (center) | |
| | ~550 | | ~ | |
| | (edges) | | (edges) | |
| Melt pressure (bar) | 93 | 149 | 128 | 125 |
| Screw speed (rpm) | 110 | 130 | 131 | 131 |
| Roll temperature | 10 | 10 | 10 | 10 |
| (° C.) | | | | |
| Motor torque (A) | 3 | 3 | 3 | 3 |
| Pulling speed (m/min) | 3.7 | 3.7 | 3.7 | 3.7 |

Films of the samples were cured via compression molding, using Teflon® sheets in order to avoid adhesion to the substrates. No significant pressure was applied (3.5 ton) in order to avoid changing much the thickness of the sheets. The molding process was performed at 160° C. for 60 minutes. After molding, the samples were cooled in a bench (concrete), with no specific cooling rate, and the Teflon® sheets were carefully removed in order to avoid damaging the sheets.

Samples were tested for water vapor transmission rate and gel content, as previously described. Water vapor transmission rate was determined following ASTM F1249, with the following conditions: 37.8° C., 1 atm, Relative humidity of 100%, with a method uncertainty of 5%, as shown in Table 15.

TABLE 15

| | Water Vapor | Water Vapor | Film |
|---|---|---|---|
| | Transmission Rate | Transmission Coefficient | thickness |
| Sample | (g/m² · day) | (μm · g/m² · day) | (μm) |
| DV001A | 30.0 | 12600 | 419 |
| DV001B | 25.5 | 10700 | 421 |
| HM728 | 33.7 | 14500 | 429 |
| EVATANE | 55.6 | 20100 | 362 |
| 3345PV | | | |

The gel contents of the films were determined via boiling xylene extraction according to the methodology previously described. The results are as follows:

TABLE 16

| Sample | Gel content (%) |
|---|---|
| DV001A | 92.4 |
| DV001B | 93.1 |
| HM728 | 95.4 |
| EVATANE 3345PV | 94.2 |

### Example 5—Aging Test (UV Degradation and Damp-Heat Test)

The aforementioned formulated films and additionally a standard commercial Sentryglas (Kuraray) were laminated between glass substrates.

The materials were put in a laminator (Radiant Solar Panel Laminator YDS-0707, Yudian Solar), under vacuum (−90 kPa), where it was heated up to 100° C. for 30 minutes in order to melt the EVA, spreading it up and filling spaces of the laminate. The application of vacuum aids in removing air and eventual volatiles from the films, preventing the formation of bubbles—vacuum was applied for 60 minutes.

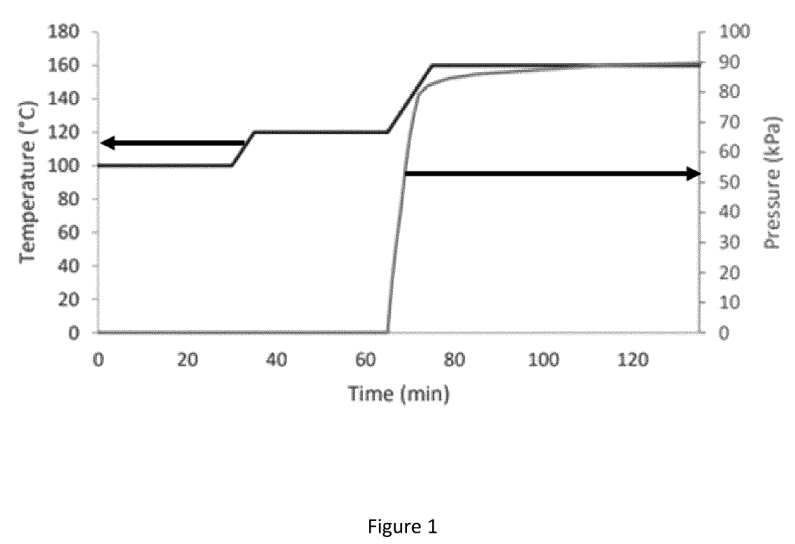

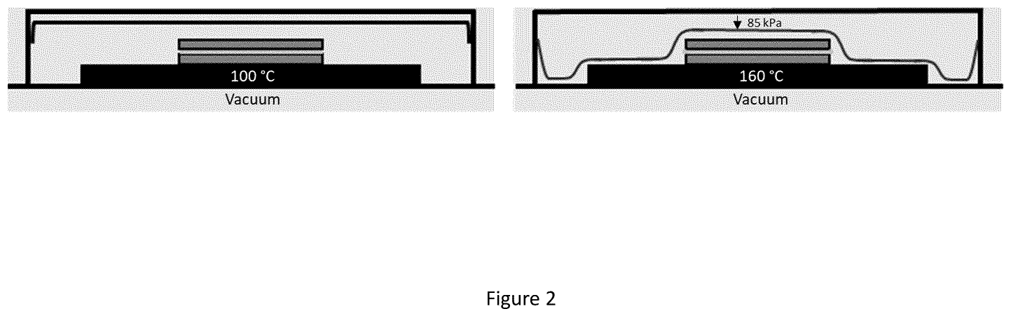

Afterwards, the temperature was raised to 120° C. for another 30 minutes (still under vacuum) in order to more efficiently eliminate residual stresses in the films, avoiding shrinkage upon curing and cooling. For the curing cycle, the temperature was then raised to 160° C. and 85 kPa of pressure was applied with a diaphragm to the laminate for 1 hour. Afterwards, samples were removed from the laminator and left under room temperature to cool off. The entire lamination cycle diagram and schematics displayed in FIGS. 1 and 2.

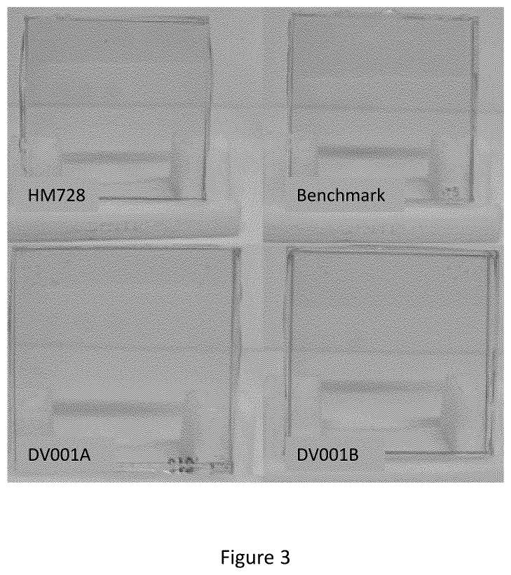

The obtained glass laminated samples are 5×5 cm squares and images of the samples after lamination process are displayed in FIG. 3.

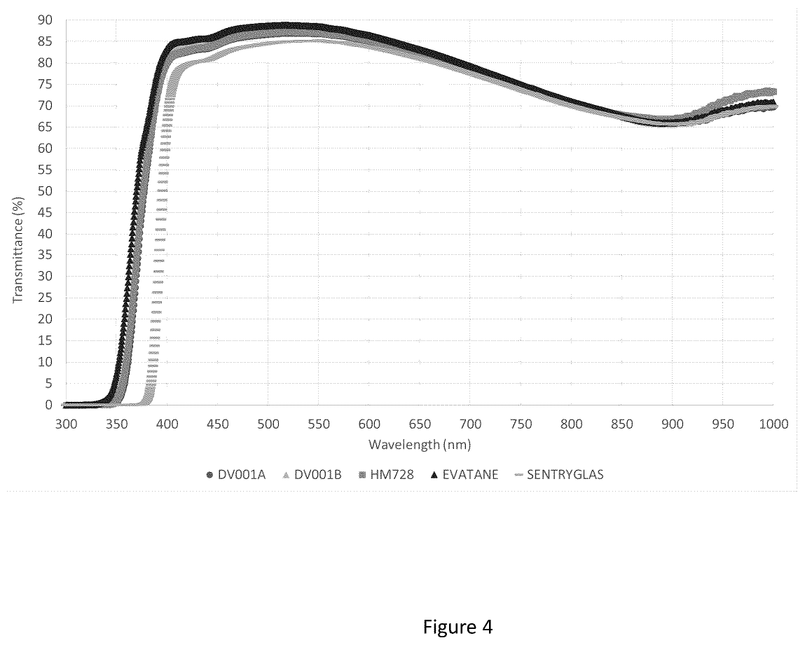

In the glass laminated samples, initial optical properties (UV/Vis spectroscopy) were measured. Transparency at different wavelengths (Shimadzu UV2600) was performed in order to assess the initial optical transmittance of the films, from wavelengths ranging from 300 to 1000 nm, before submitting the samples to UV lamp or chamber. The initial spectra of the samples are displayed in FIG. 4.

In addition, ageing tests were performed, where samples were evaluated periodically (every 3-4 days) via UV-Vis spectroscopy in order to follow and compare degradation kinetics. UV ageing was performed under continuous irradiation of 1000 W/m² (lamps: Lumixo S plasma lamp—Lumartix). Due to the heat emitted by the lamp, the samples were at an approximate temperature of 65° C. After 2000 hours, the temperature was increased to 85° C. with a hot plate in order to accelerate the degradation.

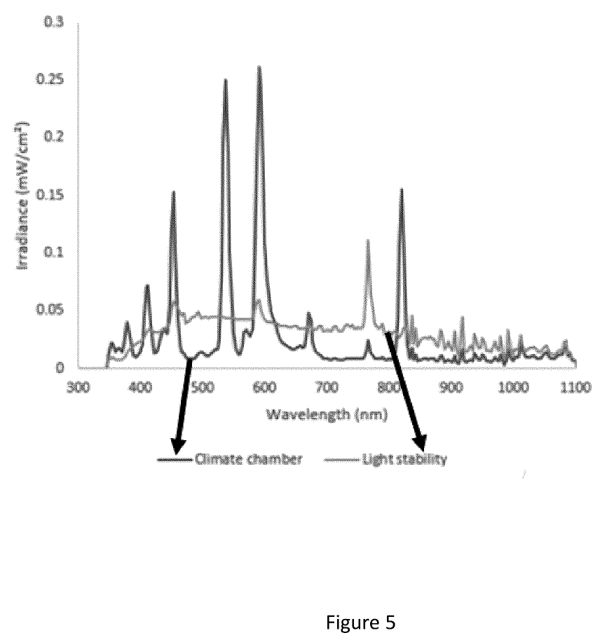

Damp-Heat Test—Accelerated degradation was performed in an environmental chamber (Blue M, CEO932-4), with high temperature and moisture content (65° C., 85% RH) and exposed to UV radiation (Halogen lamp). Spectra for the UV ageing and climate chamber of damp heat are displayed in FIG. 5).

For the generated data in both tests (UV degradation and Damp Heat), the main calculated parameter was the area of the spectrum via numerical integration with the aid of Microsoft Excel, using the trapezoidal rule, in order to quantify the overall transmittance of the sample, for all studied wavelengths. The integration for each measurement was plotted against time in order to understand the behavior of the sample during the whole test timeframe (˜3000 hours).

In UV degradation test, indexes such as the initial transmittance and the slope of transmittance vs time, which can be related to the degradation rate of the material, were calculated and compared.

### UV Degradation Test—Results

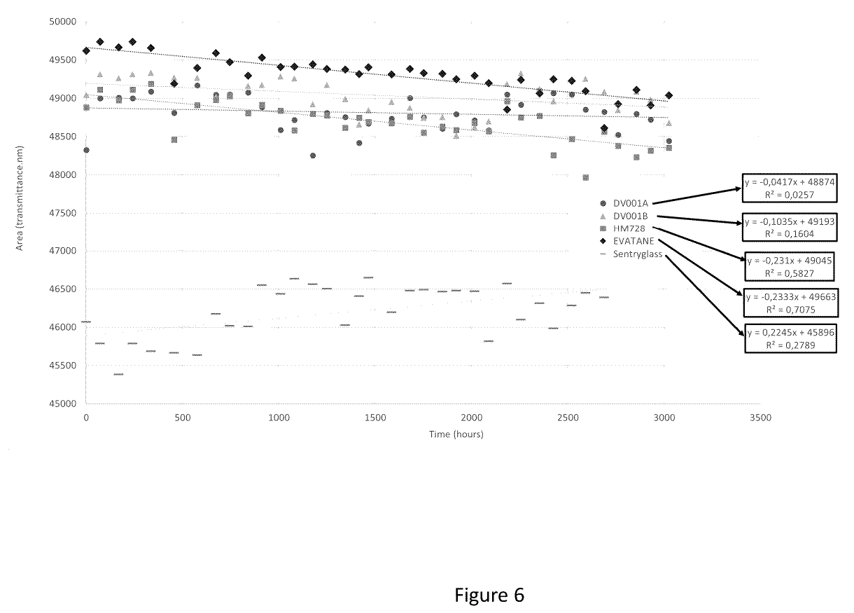

In FIG. 6, the transmittance of all samples upon UV exposure is shown. One can observe a less steep slope for the terpolymers (DV001A and DV001B) compared to the EVAs. On the other hand, Sentryglas presented a positive slope, with an increase of transmittance with time. The different behavior of Sentryglass under UV exposure can be explained by the fact that it is a different material (iomonomer). So, the direct comparison in FIG. 6 is being made considering EVAs and the terpolymers according to the present disclosure.

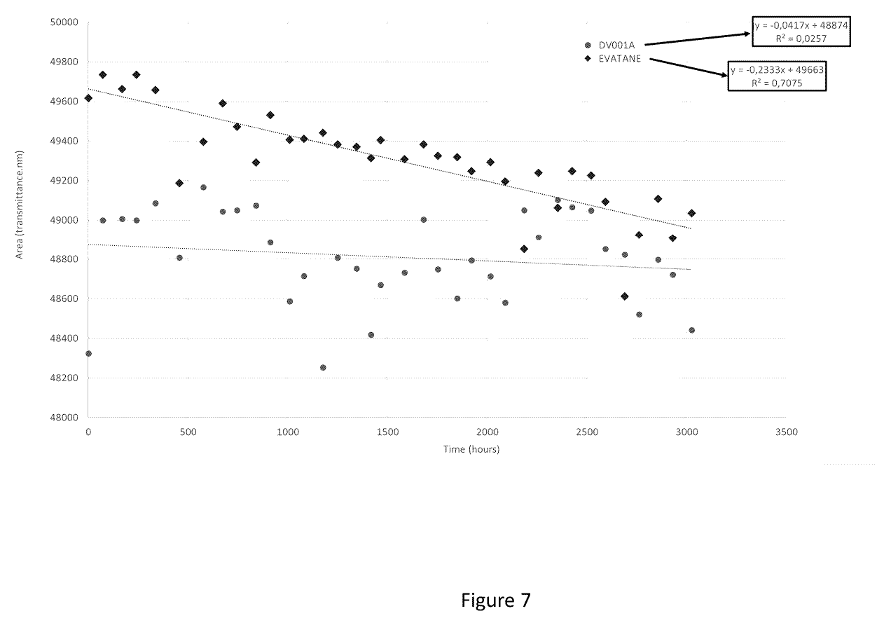

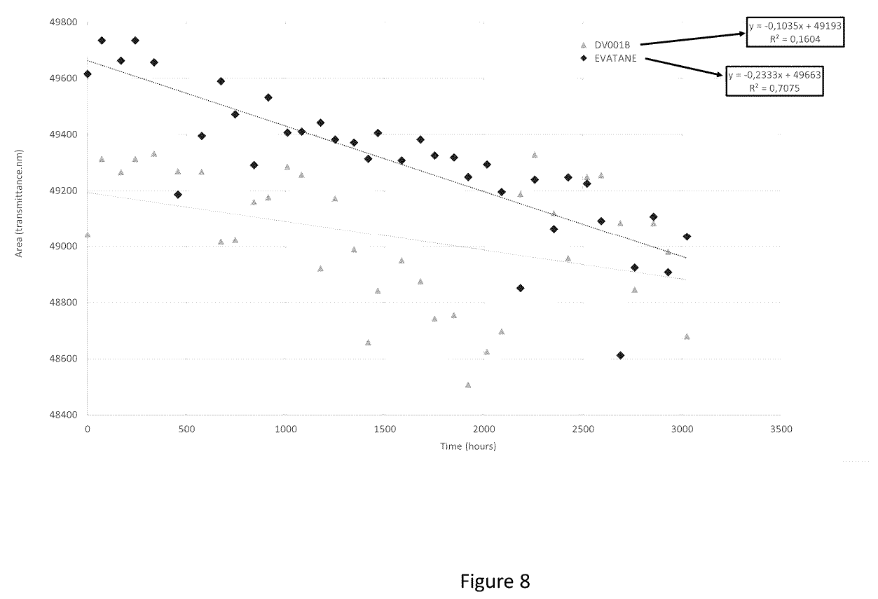

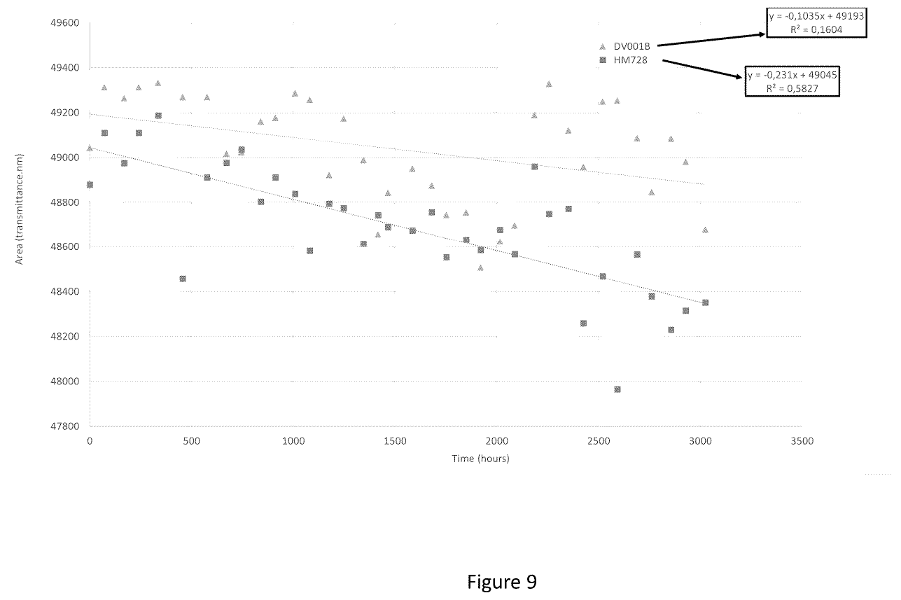

Terpolymers containing VeoVa™ 10 presented less steeper slopes (angular coefficients)—a slower decrease rate for transmittance with time—which can be related to a slower degradation rate. This is in line with the literature observed for comparisons of vinyl acetate and larger, branched vinyl ester based copolymers. Comparisons between the transmittances of the samples are plotted in FIGS. 7-9.

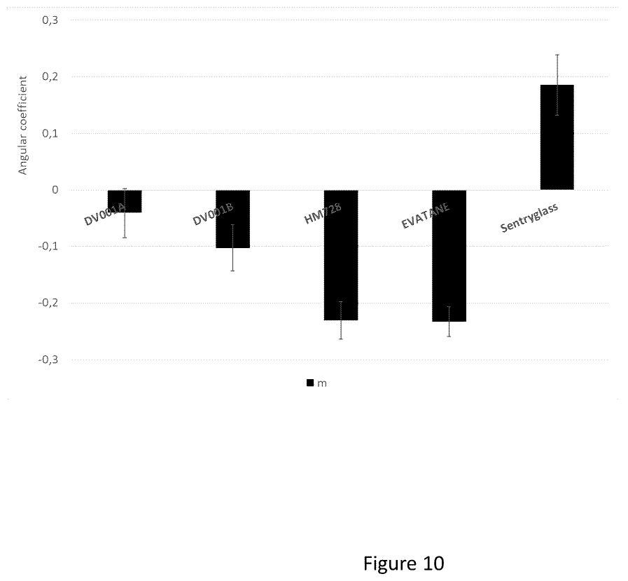

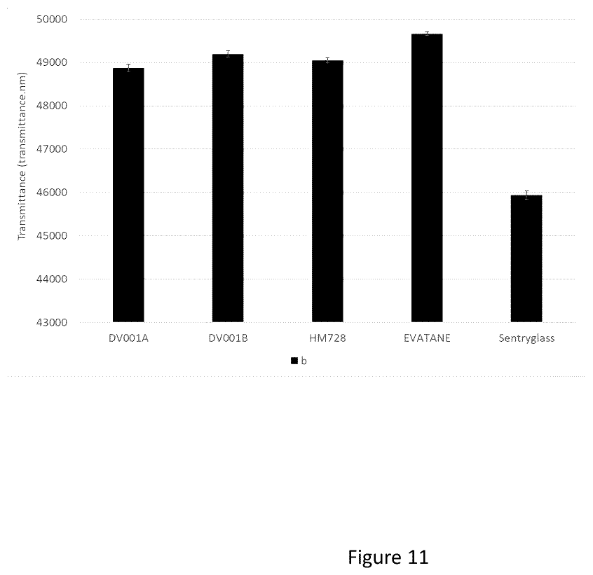

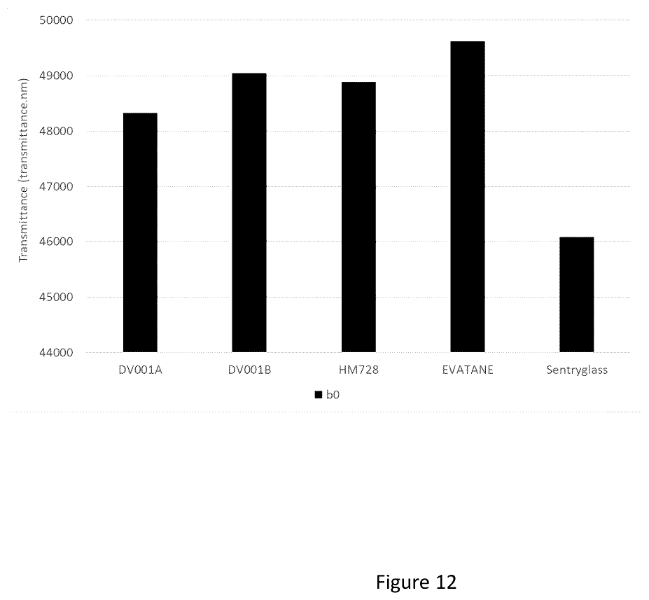

The calculated indexes from numerical integrated data (angular coefficient (m), linear coefficient (b) and initial transmittance—b0) are shown in FIGS. 10, 11 and 12.

In terms of initial transmittance, EVATANE presented the highest value—both for the measured value and its linear fit—which is in line with prior findings (film transmittance) and the theory of lower crystallinity (due to higher mol % of comonomers in an ethylene copolymer) leading to higher transmittance. DV001A and DV001B presented however, comparable values to HM728. All terpolymers and EVAs presented higher transmittance than Sentryglas. Lastly, the trends of the comparisons of the linear coefficients of the fits and the measured values were the same, and the actual values were very similar, with the exception of DV001A, which presented a slightly higher difference.

### Damp Heat Test—Results

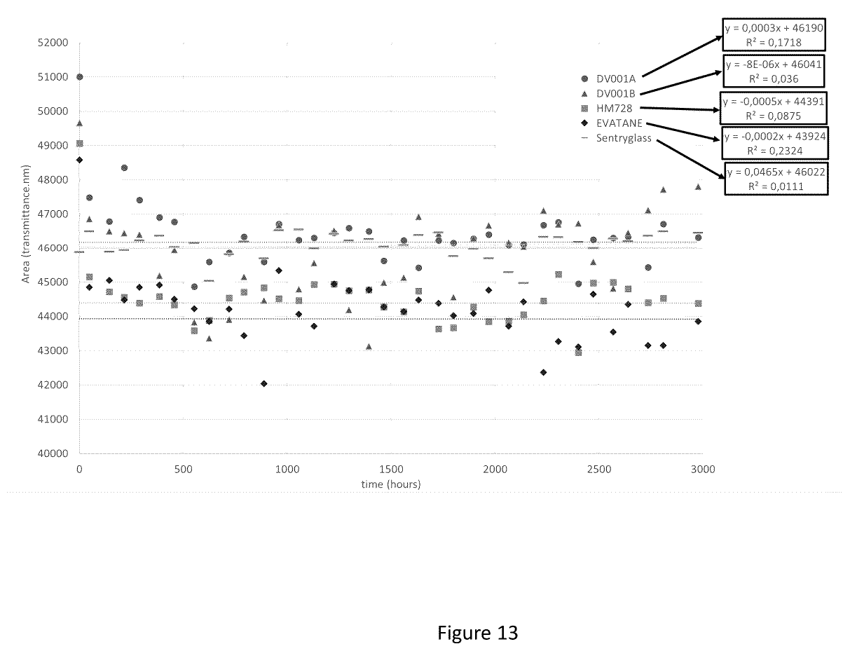

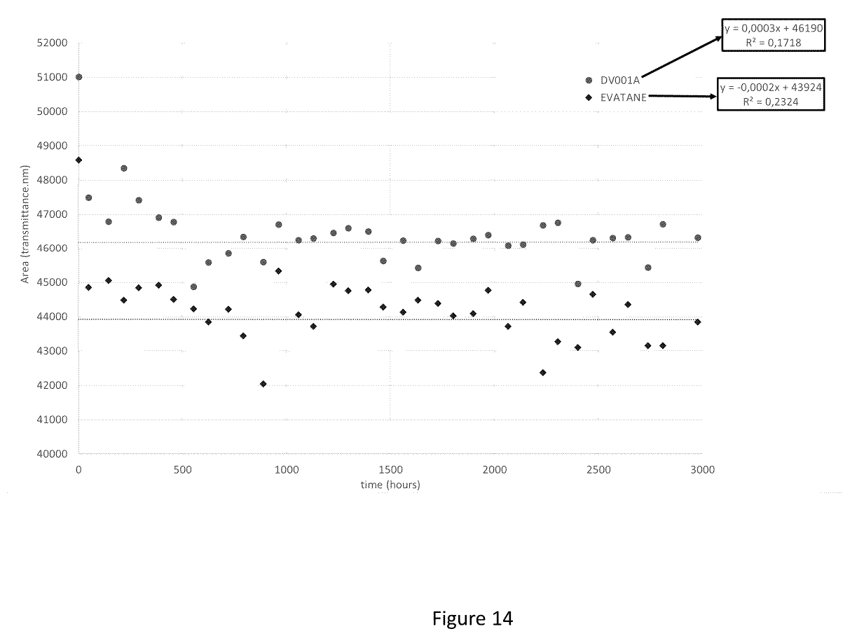

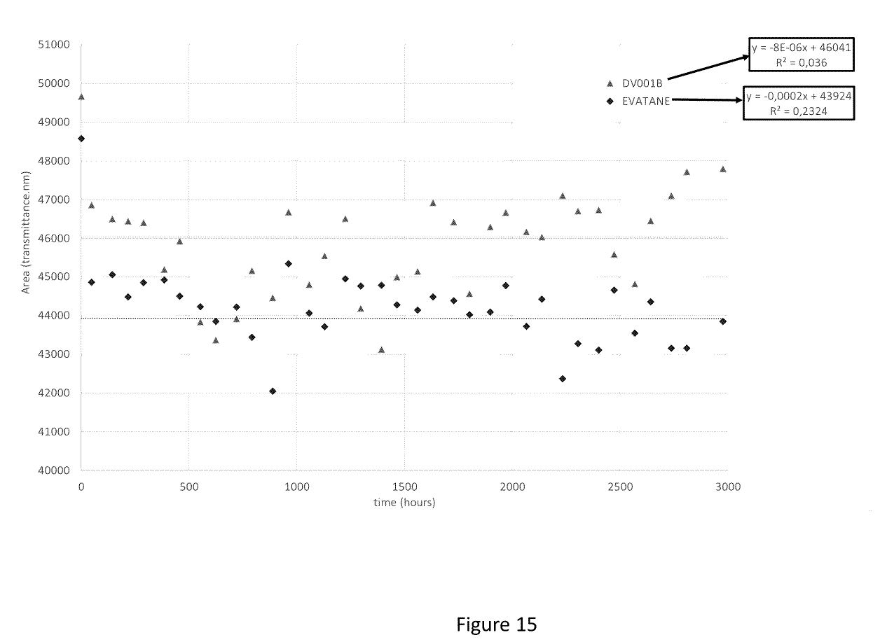

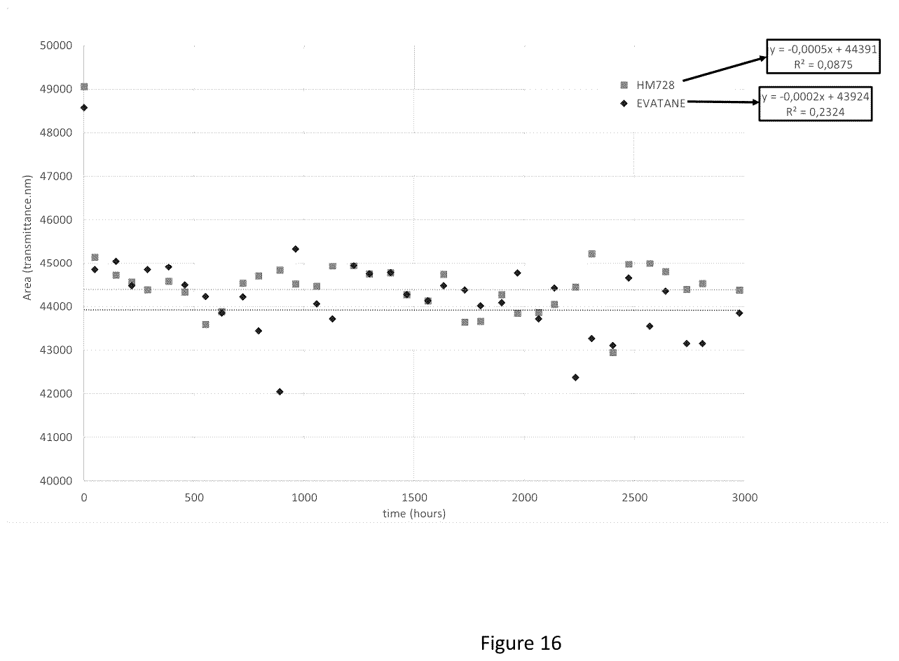

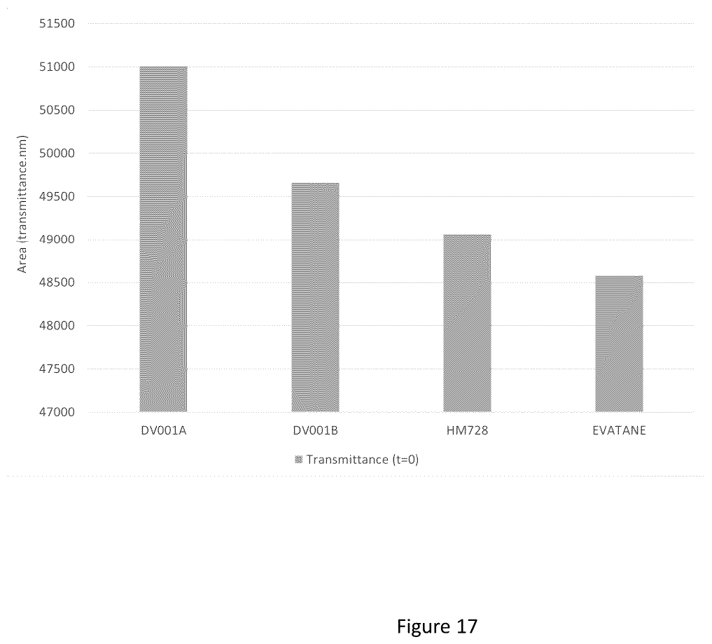

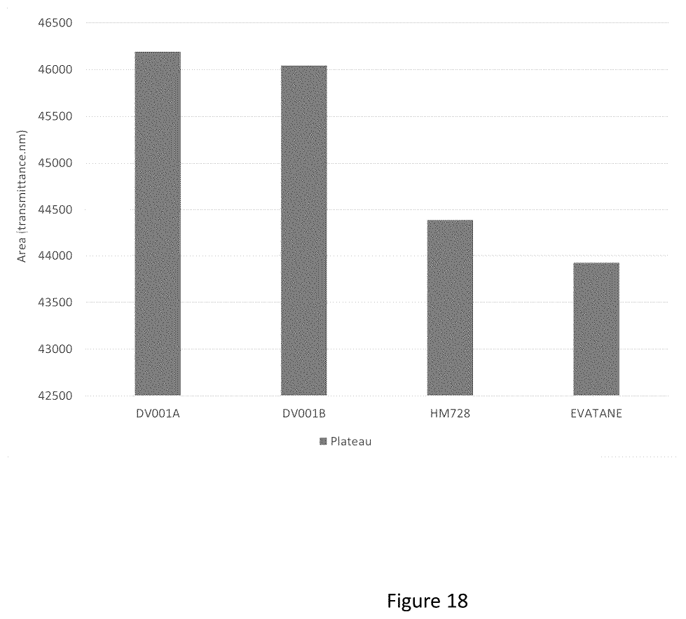

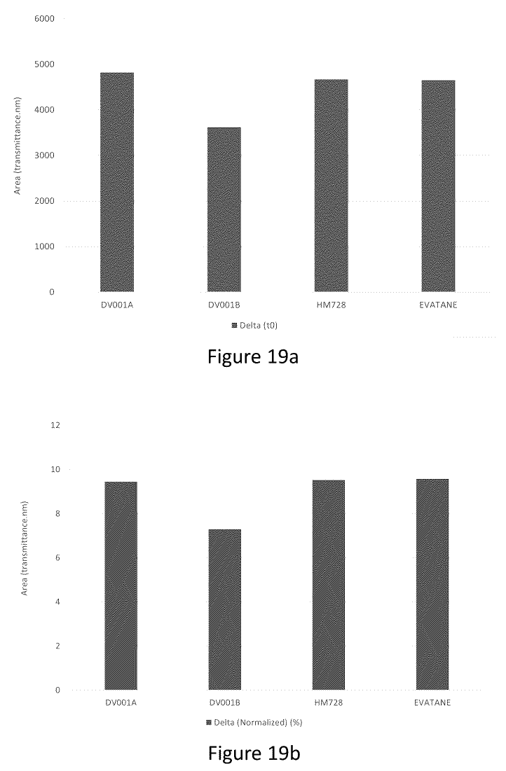

The assessment of performance for the Damp Heat Test was made considering as parameters i) the initial transmittance (t=0)—transmittance before exposure to the environmental chamber, ii) the plateau observed after the initial steep drop ((linear coefficient saw in the linear fit), and the difference (Delta) between the initial transmittance (t0) and the plateau transmittance. The plateau value was calculated by linear fit using Microsoft Excel, by adjusting the linear coefficient in the fit, where it would lead to an angular coefficient as close as possible to zero. The three parameters were plotted and compared, as it can be seen in FIGS. 13-19.

Since Sentryglas is a different material (an iomonomer), it presented a different behavior than the other laminated samples when considering the initial transmittance. However, it presented a very comparable transmittance with all EVA and terpolymers, considering their respective plateaus.

In terms of plateau values, one can see DV001A presented the largest value, and EVATANE a lower value (closely followed by HM728). Even though the difference is not necessarily large (comparing DV001A and EVATANE, it is 4.9%). The DV001B response is a remarkably close value to the DV001A response (0.32% lower than DV001A).

The difference between initial and plateau transmittances indicates how much this test affects the optical properties of the film. DV001A presented the highest value, along with both EVAs (close to 9.5%). DV001B presented a difference between initial and plateau transmittances of around 7.3%.

Hence, it seems clearly that the inventive films (especially the one comprising DV001A) presented a high plateau transmittance, and did not present any significant difference in terms of losing performance with the test, being an indication that it is suitable to this application, with potential competitive advantages if compared to films comprising traditional EVA.

### Example 6: Adhesion Test

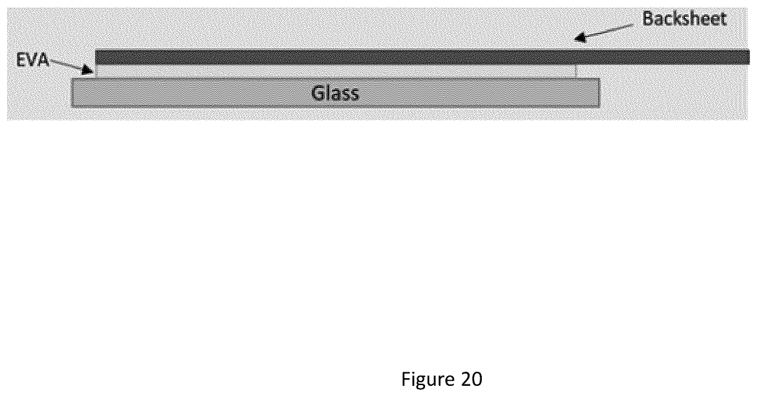

The same protocol (annealing, crosslinking parameters) was used for preparing samples to glass adhesion tests. Glass substrate with the dimensions 2.5 cm×10 cm×4 mm, a commercial backsheet material (CPX1000—crosslinked polyolefin based backsheet), and extruded films with the previously described formulations were cut to suitable dimension and they were laminated. An adhesion test was performed. Schematics displayed in FIG. 20.

Adhesion test—90° peel tests with the samples previously described (laminates of glass/film/crosslinked polyolefin) were performed according to ASTM D3330, with a speed of 300 mm/min, in specimens with a length of 10 cm (being 9 cm with the EVA adhesive) and a width of 2.5 cm. 3 tests were performed by material.

In terms of data analysis, average values of force (N), work (N·mm) and energy (N/mm) were calculated, where work and energy were obtained using numerical integration (trapezoidal rule) with the force vs displacement raw data. All samples were compared for work and energy, values ranging from 0 to 85 mm were used, reducing differences in total tested length.

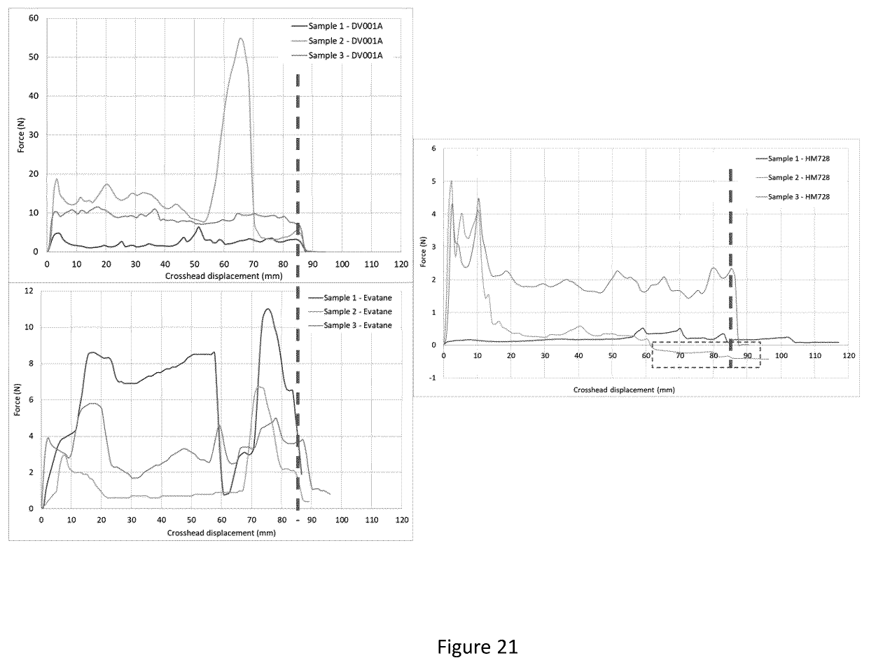

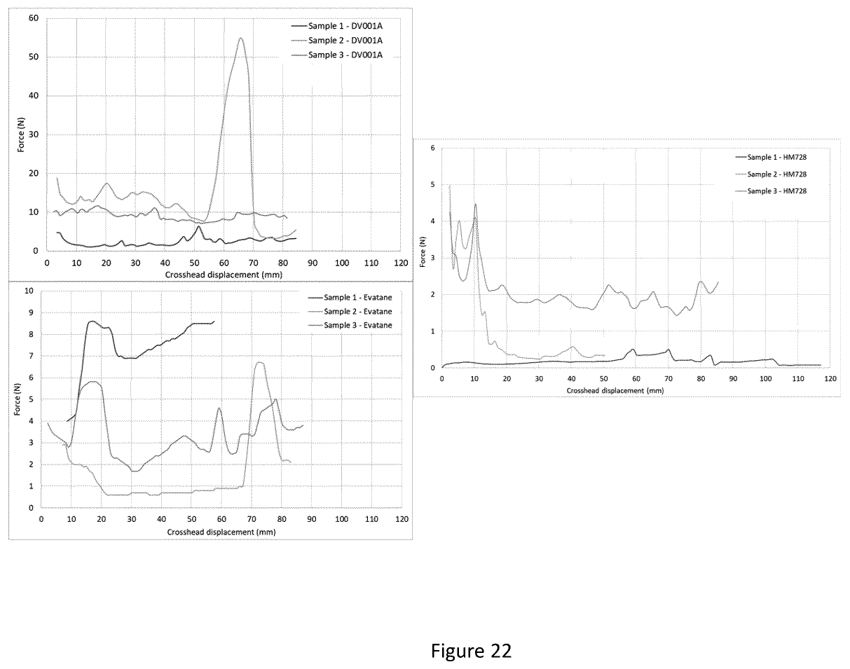

On the other hand, for average force, more specific regions of the plot were used, taking out of consideration initial and end regions and steep increases and decreases of measured force in order to have a better representation of an average value. The plots are displayed in FIGS. 21 and 22 (scales among plots are different) and the numerical results, calculated are displayed in tables 17-19.

TABLE 17
Average force for adhesion tests.

| Average force | HM728 | EVATANE | DV001A |
|---|---|---|---|
| (variable regions) | (N) | (N) | (N) |
| Sample 1 | 0.18 | 7.47 | 2.42 |
| Sample 2 | 1.07 | 1.67 | 15.76 |
| Sample 3 | 2.05 | 3.40 | 9.13 |
| Average (N) | 1.10 | 4.18 | 9.10 |
| Standard deviation | 0.76 | 2.43 | 5.45 |
| Contact angle (°) | 83.7 | 94.4 | 86.6 |

TABLE 18
Average work for adhesion tests.

| Integration - | HM728 | EVATANE | DV001A |
|---|---|---|---|
| (up to 85 mm) | (N · mm) | (N · mm) | (N · mm) |
| Sample 1 | 17.18 | 543.66 | 206.48 |
| Sample 2 | 58.94 | 136.69 | 1314.69 |
| Sample 3 | 172.36 | 285.67 | 763.70 |
| Average (N · mm) | 82.83 | 322.01 | 761.62 |
| Standard deviation | 65.56 | 168.12 | 452.43 |

TABLE 19
Average energy for adhesion tests.

| Integration | HM728 | EVATANE | DV001A |
|---|---|---|---|
| (up to 85 mm) | (N/mm) | (N/mm) | (N/mm) |
| Sample 1 | 0.01 | 0.26 | 0.10 |
| Sample 2 | 0.03 | 0.06 | 0.62 |
| Sample 3 | 0.08 | 0.13 | 0.36 |
| Average (N/mm) | 0.04 | 0.15 | 0.36 |
| Standard deviation | 0.03 | 0.08 | 0.21 |

It is possible to notice by all metrics that DV001A outperformed all other grades—including EVATANE 3345PV. The lowest adhesion forces were found for HM728. VA, VeoVa and total comonomer content was not directly correlated to adhesive strength, and no relationship could be observed with the contact angle (related to surface energy) and MFR (which could be related to the ability to spread and efficiently wet the substrates).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

What is claimed:

1. A film, comprising a polymer composition comprising:
a polymer produced from ethylene, one or more branched vinyl ester monomers, and optionally, vinyl acetate, with an ethylene content in an amount ranging from 40 to 99.9 wt %, and having a melt index (I₂) from 0.1 to 100 g/10 min, measured according to ASTM D1238 (190° C. and load of 2.16 kg).

2. The film according to claim 1, wherein the polymer composition further comprises one or more of:
a crosslinking agent in an amount of 0.01 to 10 phr;
a crosslinking coagent in an amount of 0.01 to 5 phr;
a primary antioxidant in an amount of 0.01 to 5 phr;
a secondary antioxidant in an amount of 0.01 to 5 phr;
a light stabilizer in an amount of 0.01 to 5 phr;
an UV absorber in an amount of 0.01 to 5 phr;
an adhesion promoter in an amount of 0.01 to 5 phr; or
optionally, at least one additive selected from the group consisting of thermal stabilizers, plasticizers, rubbers, elastomers, fillers, and combinations thereof.

3. The film according to claim 1, wherein the one or more branched vinyl ester monomers have the general structure (II): 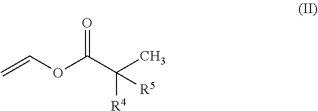
wherein R⁴ and R⁵ have a combined carbon number of 7.

4. The film according to claim 1, wherein the polymer has a total comonomer content ranging from 10 wt % to 60 wt %.

5. The film according to claim 1, wherein the polymer has a density ranging from 0.8 g/cm³ to 1.3 g/cm³, measured according to ASTM D792.

6. The film according to claim 1, wherein the polymer has a melt index (I₂) ranging from 1 g/10 min to 100 g/10 min, measured according to ASTM D1238 (190° C. and load of 2.16 kg).

7. The film according to claim 1, wherein the polymer has one or more of the following properties:
a melting temperature of less than 90° C., measured according to ASTM D3418;
volumetric electrical resistivity greater than 1×10¹⁴ Ohm·cm, measured according to ASTM D257;
a Shore A Hardness of less than 90, measured according to ASTM D2240;
a Vicat Softening Point of less than 50° C., measured according to ASTM D1525;
a contact angle greater than 80°, measured according to ASTM D5946;
an optical transmittance of greater than 85%, measured according to ASTM D1003;
a haze of less than 10%, measured according to ASTM D1003;
a water vapor transmission coefficient of less than 22000 μm·g/m²·day, measured according to ASTM F1249;
a stress at break of at least 5 MPa, measured according to ASTM D638;
a strain at break of at least 500%, measured according to ASTM D638;
a UV cut-off wavelength of 380 nm;
an optical clarity of greater than 80%, measured according to ASTM D1003; and
glass transition temperature of less than −19° C. via tan δ and lower than −29° C. via loss modulus, as measured via DMA, tensile fixture, tension °/min, according to ASTM D4065.

8. The film according to claim 1, wherein the film is crosslinked.

9. The film according to claim 1, wherein the film exhibits a gloss at 45° of at least 77%, measured according to ASTM D2457.

10. The film according to claim 1, wherein the film exhibits a gloss at 60° of at least 90%, measured according to ASTM D2457.

11. A method of producing the film according to claim 1, the method comprising:
blending the polymer composition, comprising:
a polymer produced from ethylene, one or more branched vinyl ester monomers, and optionally, vinyl acetate; and
optionally: a peroxide; a crosslinking coagent; a primary antioxidant; a secondary antioxidant; a light stabilizer; an UV absorber; an adhesion promoter, and thermal stabilizers, plasticizers, rubbers/elastomers, fillers, and combinations thereof;
where the blending method comprises using a twin screw extruder, single screw extruder, kneader, banbury mixer, mixing roller, or a cast film extruder; and
producing a film having a thickness in the range of 5 to 800 μm, via cast film extrusion, blown film extrusion, or calendaring.

12. The method according to claim 11, wherein the film thickness is in the range of 50 to 1000 μm.

13. An article comprising a substrate and the film according to claim 1.

14. The article according to claim 13, wherein the substrate is a solar cell.

15. A solar cell encapsulant comprising a film according to claim 1.

16. A laminate comprising a glass substrate and a film according to claim 1 on the glass substrate.

17. The laminate according to claim 16, wherein the laminate further comprises a backsheet comprising a polymeric substrate or a second glass substrate.

18. The laminate according to claim 16, wherein the laminate has work of adhesion of at least 150 N·mm according to ASTMD3330.

19. The laminate according to claim 16, wherein the laminate has a decrease in total light transmittance upon a UV lamp ageing test (1000 W/m², 65° C.) below 1%.

20. The laminate according to claim 16, wherein the laminate has a decrease in total light transmittance upon a damp heat test (65° C., 85% relative humidity and UV exposure) below 12%.

21. A method of manufacturing an article, comprising:
applying a film according to claim 1 to a substrate.

22. The method of claim 21, wherein the applying comprises: vacuum laminating the film on the substrate, wherein the film encapsulates and/or bonds a photovoltaic device to the substrate.

23. The method of claim 21, wherein the applying comprises: encapsulating a photovoltaic device by crosslinking the film via exposure to a vacuum lamination process, with pressures from 5 to 200 kPa, temperature from 130 to 250° C., and within a time frame from 1 minute to 2 hours.
